(19) United States
(12) Patent Application Publication
(10) Pub. No.: US 2025/0327173 A1
(43) Pub. Date: Oct. 23, 2025

(54) METAL SUBSTRATE COATINGS

(71) Applicants: Hong Kong Baptist University, Hong Kong (HK); Cathay Photonics Limited, Hong Kong (HK)

(72) Inventors: Kok Wai CHEAH, Hong Kong (HK); Shing Chi TSE, Hong Kong (HK); Suet Ying CHING, Hong Kong (HK); Wing Yui LAM, Hong Kong (HK); Yu Wai CHAN, Hong Kong (HK); Wing Hang CHAN, Hong Kong (HK); Tian HAN, Hong Kong (HK)

(21) Appl. No.: 18/261,674

(22) PCT Filed: Jan. 25, 2022
(86) PCT No.: PCT/CN2022/073873

§ 371 Date: Jul. 17, 2023

Related U.S. Application Data
(60) Provisional application No. 63/141,461, filed on Jan. 25, 2021.

(51) Int. Cl. C23C 14/46; C23C 14/08; C23C 14/10; C23C 14/30

(52) U.S. Cl. CPC C23C 14/46; C23C 14/081; C23C 14/083; C23C 14/10; C23C 14/30

(57) ABSTRACT

A composite multi-layer thin film structure deposited on a metal substrate, the method thereof are provided. The film structure includes a first thin film layer on a surface of the metal substrate including Al₂O₃ with a thickness ranging from approximately 100 nm to 150 nm and a refractive index of approximately 1.7. A second thin film layer is positioned on the first thin film layer including SiO₂ with a thickness ranging from approximately 80 nm to 120 nm and a refractive index of approximately 1.4. A third thin film is positioned on the second thin film layer including TiO₂ with a thickness ranging from approximately 50 nm to 80 nm and a refractive index of approximately 2.2. A fourth thin film layer is positioned on the third film layer including Al₂O₃ with a thickness ranging from approximately 60 nm to 90 nm. The total thickness of the multi-layer thin film structure ranges from approximately 280 nm to 400 nm. The composite thin film has a high abrasion resistance, an excellent adhesiveness and consistent appearance color with bare metal substrate.

### FIELD OF THE INVENTION

This invention relates to a thin film coating including sapphire (Al₂O₃), and, optionally, SiO₂, and ZrO₂/TiO₂ coated on a metal substrate; the thin films have high abrasion resistance, excellent adhesion, and a consistent color appearance with the base metal substrate.

### BACKGROUND

A variety of treatments such as coating, laminating or the like are applied to metal substrates or plated metal substrates which are to be used for various purposes so that those metal substrates can have characteristics such as an attractive appearance, abrasion resistance and/or insulation. For this purpose, coating with electron-beam (EB) systems or sputtering systems may be applied to the surface of metal substrates for substrate-treating. Thin film coatings are made for improving the abrasion resistance and the products with metal substrates are attractive while being able to perceive the underlying metal substrate.

In view of the recent growing concern for the environment, metal waste has been identified as a serious problem. Consequently, protective thin films/coatings on metal substrates can improve their service life and lead to a reduction in metal usage. Coating technology has been developed in order to have a protective performance; however, the performance of protective coatings still requires considerable improvement.

It is an objective of the current invention to provide an electron beam and/or sputtering-based transparent or translucent thin film coating on metal substrates that have characteristics such as attractive appearance, abrasion resistance and/or insulation.

### SUMMARY OF THE INVENTION

In accordance with a first aspect of the present invention, there is provided a composite multi-layer thin film structure deposited on a metal substrate by electron beam evaporation or sputtering. The multi-layer thin film structure includes a metal substrate and a first thin film layer of on a surface of the metal substrate that includes Al₂O₃ with a thickness ranging from approximately 100 nm to 150 nm and a refractive index of approximately 1.7. A second thin film layer is positioned on the first thin film layer, the second thin film layer includes SiO₂ with a thickness ranging from approximately 80 nm to 120 nm and a refractive index of approximately 1.4. A third thin film layer is positioned on the second thin film layer and includes TiO₂ with a thickness ranging from approximately 50 nm to 80 nm and a refractive index of approximately 2.2. A fourth thin film layer is positioned on the third film layer and includes Al₂O₃ with a thickness ranging from approximately 60 nm to 90 nm. The total thickness of the multi-layer thin film structure deposited on the metal substrate ranges from approximately 280 nm to 400 nm.

In a further aspect, the multi-layer thin film structure includes a fifth thin film layer positioned on the fourth thin film layer comprising SiO₂ with a thickness ranging from approximately 10 nm to 20 nm.

In a further aspect, the multi-layer thin film structure is deposited at a temperature of approximately 25 degrees Celsius.

In a further aspect the multi-layer thin film structure further includes an anti-fingerprint (AF) coating on the fifth thin film layer or, alternatively, directly on the four-layer structure.

In a further aspect the multi-layered structure has a stainless steel substrate.

In another aspect the present invention relates to a method for depositing a composite multi-layered thin film structure on a metal substrate by electron beam evaporation. A first thin film layer is deposited on a surface of a metal substrate comprising Al₂O₃ with a thickness ranging from approximately 100 nm to 150 nm and a refractive index of approximately 1.7. A second thin film layer is deposited on the first thin film layer, the second thin film layer including SiO₂ with a thickness ranging from approximately 80 nm to 120 nm and a refractive index of approximately 1.4.

A third thin film layer is deposited on the second thin film layer, the third film layer comprising TiO₂ with a thickness ranging from approximately 50 nm to 80 nm and a refractive index of approximately 2.2. A fourth thin film layer is deposited on the third thin film layer, the fourth thin film layer comprising Al₂O₃ with a thickness ranging from approximately 60 nm to 90 nm. A total thickness of the multi-layered thin film structure deposited on the metal substrate ranges from approximately 280 nm to 400 nm.

In a further aspect, the method includes depositing a fifth thin film layer on the fourth thin film layer, the fifth thin film layer comprising SiO₂ with a thickness ranging from approximately 10 nm to 20 nm.

In a further aspect, the method includes depositing an anti-fingerprint coating on the fifth thin film layer

In a further aspect, the thin film layers are deposited at a temperature of approximately 15-25 degrees Celsius.

In a further aspect, the thin film layers are deposited without heating or cooling of the metal substrate, without heating or cooling of the thin film material targets, and without heating or cooling of the deposition environment.

In a further aspect, the thin film layers are deposited without preheating or post-heating, or pre-cooling or post cooling of the metal substrate, the thin film material targets or the deposition environment.

In a further aspect, the thin film layers are deposited with no post annealing of the deposited thin film on the metal substrate.

In a further aspect, the thin film layers are deposited sequentially while maintaining a vacuum condition of an electron beam or sputtering deposition system

In a further aspect, the metal substrate comprises stainless steel.

In another aspect, the present invention provides an anti-abrasion protective thin film structure deposited on a metal substrate by electron sputtering. A metal substrate has at least a first layer positioned on a surface of the metal substrate. The first layer includes Al₂O₃ with a thickness up to 2000 nm and a refractive index of about 1.7.

In another aspect, the anti-abrasion protective thin film structure further includes second layer comprising SiO₂ layer positioned on a surface of the first layer comprising Al₂O₃.

In another aspect, the anti-abrasion protective thin film structure further includes an anti-fingerprint coating positioned on a surface of the first layer comprising Al₂O₃.

In another aspect, the anti-abrasion protective thin film structure includes an anti-fingerprint coating positioned on a surface of the second layer comprising SiO₂.

In some aspects the thin films layers of the present layer include only the listed materials; it has been determined that layer structures with only these materials at these thicknesses have particularly beneficial optical/appearance properties as seen in the Examples, discussed below.

Those skilled in the art will appreciate that the invention described herein is susceptible to variations and modifications other than those specifically described.

The invention includes all such variation and modifications. The invention also includes all of the steps and features referred to or indicated in the specification, individually or collectively, and any and all combinations or any two or more of the steps or features.

Other aspects and advantages of the invention will be apparent to those skilled in the art from a review of the ensuing description.

### BRIEF DESCRIPTION OF THE DRAWINGS

The above and other objects and features of the present invention will become apparent from the following description of the invention, when taken in conjunction with the accompanying drawings, in which:

FIG. 1 shows a general thin film structure of the present invention;

FIG. 2 shows one specific thin film structure of the present invention;

FIG. 3 shows reflectance for 1 layer of Al₂O₃ (65), Al₂O₃ (60), Al₂O₃ (55), Al₂O₃ (50) and bare substrate-1;

FIG. 4 shows reflectance of 1 layer of Al₂O₃ (65) at different viewing angles;

FIG. 5 shows reflectance of 5-layer structure: Si₃N₄ (135)/SiO2 (50)/ZrO₂ (10)/TiO₂ (45)/Al₂O₃ (90) at different viewing angle (0°, 30°, 60°);

FIG. 6 shows reflectance comparison of three different thickness combination for 5-layer structure: Sub-2/Si₃N₄/SiO₂/ZrO₂/TiO₂/Al₂O₃, viewing angle −0°;

FIG. 7 shows the reflectance comparison of 5-layer structure with ZrO₂ in different viewing angles (0°, 30°, 60°);

FIG. 8 shows the photos for 4-layer structure Al₂O₃ (145)/SiO₂ (100)/TiO₂ (160)/Al₂O₃ (75) with and without SiO₂+AF coating;

FIG. 9 shows photo of Substrate-1; stainless steel in house-metal-mask-0.1 mm;

FIG. 10 shows the property (N-refractive index, K-absorption coefficient) of substrate-1;

FIG. 11 shows the reflectance comparison for sample-1 and bare substrate-1;

FIG. 12 shows abrasion testing of sample-1; 4-Layer Structure: Al₂O₃ (145)/SiO₂ (100)/TiO₂ (60)/Al₂O₃ (75)+SiO₂ (10)+AF.

FIG. 13 shows standard viewing angle. That means, normally the viewer observe object from front-standard viewing angle (0°);

FIG. 14 shows sample color examples of two groups (Negative vs Positive);

FIG. 15 shows color testing device (Ocean Optics 2000+) and relative software (Ocean View);

FIG. 16 shows sample stage and parameter set, color testing result in software (Ocean View);

FIG. 17 shows device and steel wool for abrasion testing;

FIG. 18 shows the abrasion testing parameter (for T2 testing) on metal substrates;

FIG. 19 shows a sample photo for sample analysis (Color & Abrasion Resistance);

FIG. 20 shows the photo of sample-1-2;

FIG. 21 shows a photo of substrate-2;

FIG. 22 shows the property (N-refractive index, K-absorption coefficient) of substrate-2;

FIG. 23 shows the reflectance comparison for sample-2 and bare substrate-2;

FIG. 24 shows the comparison of abrasion testing between bare substrate-2 and Sample-2;

FIG. 25 shows a photo of substrate-3;

FIG. 26 shows the property (N-refractive index, K-absorption coefficient) of substrate-3;

FIG. 27 shows the reflectance comparison of sample-3 in different viewing angle (0°, 30°) and bare substrate-3;

FIG. 28 shows the comparison of abrasion testing between bare substrate-3 and Sample-3;

FIG. 29 shows the nano-hardness of bare substrate-3 and sample-3;

FIG. 30 shows a photo of substrate-4;

FIG. 31 shows the property (N-refractive index, K-absorption coefficient) of substrate-4;

FIG. 32 shows the reflectance comparison of sample-4 (three samples of the same substrate and structure) and bare substrate-3;

FIG. 33 shows the color comparison of Sample-4 in CIExy graph;

FIG. 34 shows the comparison of abrasion testing between bare substrate-4 and Sample-4;

FIG. 35 shows the nano-hardness of bare substrate-4 and sample-4;

FIG. 36 shows a photo of substrate-5;

FIG. 37 shows the property (N-refractive index, K-absorption coefficient) of substrate-5;

FIG. 38 shows the color comparison of Sample-5 and Substrate-5 in CIExy graph;

FIG. 39 shows the photos of Sample-5 in different viewing angle (0°, 30°, 60°);

FIG. 40 shows the operating schematics of an EB evaporation system;

FIG. 41 shows bare stainless steel substrates with different colors;

FIG. 42 shows abrasion conditions with Model 339A, #0000 Alligator, 250 g, 60 cpm, 10×10 mm², ˜3 cm, 10 vs 100 cycles; obvious scratches appeared after #0000 abrasion even for 10 cycles; #0000 is the roughness of the steel wool wire;

FIG. 43 shows structure: SS/SiO₂ (10 nm)/AF (30); SiO₂ by e-beam evaporation; AF by thermal evaporation; at viewing angles 0°, near 0°, 30° and 60°; this test is to determine if the SiO₂/AF layer can affect the color; a small change in the color of SS-CN190425 after adding 10 nm SiO₂ layer on it and no significant angle-dependence of the sample with 10 nm SiO₂ layer

FIG. 44 shows abrasion conditions with Model 339A, #0000 Alligator, 250 g, 60 cpm, 10×10 mm², ˜3 cm, 100 cycles;

FIG. 45 shows abrasion conditions with Model 339A, #0000 Alligator, 1000 g vs 250 g, 60 cpm, 10×10 mm², ˜3 cm, 100 cycles;

FIG. 46 shows structure: SS/SiO₂ (10)/AF (30) at viewing angles 0°, near 0°, 30° and 60; abrasion conditions: Model 339A, #0000 Alligator, 250 g, 60 cpm, 10×10 mm², ˜3 cm, 100 cycles; for samples yellow-gold, polished and rose-gold, polished;

FIG. 47 shows structure: SS/SiO₂ (10)/AF (30) at viewing angle; abrasion conditions: Model 339A, #0000 Alligator, 250 g, 60 cpm, 10×10 mm², ˜3 cm, 100 cycles; matte+polished+brush;

FIG. 48 shows samples with fabrication method: E-beam evaporation, EBS-500; ML-TiO₂ structure: SS/Al₂O₃ (145)/SiO₂ (100)/TiO₂ (60)/Al₂O₃ (75)/SiO₂ (10); ML-multi-layer; (xxx) is the layer thickness in nm;

FIG. 49 shows samples with structure: SS/Al₂O₃ (145)/SiO₂ (100)/TiO₂ (60)/Al₂O₃ (75)/SiO₂ (10); with rose-gold, polish+brush; rose-gold, brush and rose-gold, polish at measured total thickness on SLG=420.5 mm at viewing angles 0°, near 0°, 30° and 60°;

FIG. 50 shows samples with structure: SS/Al₂O₃ (145)/SiO₂ (100)/TiO₂ (60)/Al₂O₃ (75)/SiO₂ (10); with rose-gold, polish+brush; rose-gold, brush and rose-gold, polish at measured total thickness on SLG=371.7 nm at viewing angles 0°, near 0°, 30° and 60°;

FIG. 51 shows samples with structure: SS/Al₂O₃ (145)/SiO₂ (100)/TiO₂ (60)/Al₂O₃ (75)/SiO₂ (10); with rose-gold, polish+brush; rose-gold, brush and rose-gold, polish on SLG (Soda Lime Glass) at viewing angles 0°, near 0°, 30° and 60°;

FIG. 52 shows samples with structure: SS/Al₂O₃ (145)/SiO₂ (100)/TiO₂ (60)/Al₂O₃ (75)/SiO₂ (10)/AF (30); with rose-gold, mirror+brush on SLG at viewing angles 0°, near 0°, 30° and 60°;

FIG. 53 shows samples with structure: SS/Al₂O₃ (145)/SiO₂ (100)/TiO₂ (60)/Al₂O₃ (75)/SiO₂ (10)/AF (30); with rose-gold, mirror+brush on SLG at viewing angles 80°;

FIG. 54 shows samples with structure: SS/Al₂O₃ (145)/SiO₂ (100)/TiO₂ (60)/Al₂O₃ (75)/SiO₂ (10)/AF (30); with minor scratches after 100 cycles;

FIG. 55 shows samples with structure: SS/Al₂O₃ (145)/SiO₂ (100)/TiO₂ (60)/Al₂O₃ (75)/SiO₂ (10)/AF (30); after #0000 abrasion for 10 cycles;

FIG. 56 shows samples with structure: SS-DK180723RB/M/P; ML-TiO₂:SS/Al₂O₃ (145)/SiO₂ (100)/TiO₂ (60)/Al₂O₃ (75)/SiO₂ (10);

FIG. 57 shows the plot of reflectance (%) vs wavelength (nm) for samples with structure ML-TiO₂:SS/AlO₃ (145)/SiO₂ (100)/TiO₂ (60)/Al₂O₃ (75)/SiO₂ (10); with mirror/polished.

FIG. 58 shows the CIE1931 diagram chromatic coordinates of the samples described in FIG. 57;

FIG. 59 shows the plot of reflectance (%) vs wavelength (nm) for samples with structure ML-TiO₂:SS/Al₂O₃ (145)/SiO₂ (100)/TiO₂ (60)/Al₂O₃ (75)/SiO₂ (10); with brush;

FIG. 60 shows the CIE1931 diagram chromatic coordinates of the samples described in FIG. 59;

FIG. 61 shows the plot of reflectance (%) vs wavelength (nm) for samples with structure ML-TiO₂:SS/Al₂O₃ (145)/SiO₂ (100)/TiO₂ (60)/Al₂O₃ (75)/SiO₂ (10); with matte;

FIG. 62 shows the CIE1931 diagram chromatic coordinates of the samples described in FIG. 61;

FIG. 63 shows samples with Substrate: SS-DK180723 GB/M/P; ML-TiO₂:SS/Al₂O₃ (145)/SiO₂ (100)/TiO₂ (60)/Al₂O₃ (75)/SiO₂ (10).

FIG. 64 shows the plot of reflectance (%) vs wavelength (nm) for samples with ML-TiO₂:SS/Al₂O₃ (145)/SiO₂ (100)/TiO₂ (60)/Al₂O₃ (75)/SiO₂ (10);

FIG. 65 shows the CIE1931 diagram chromatic coordinates of the samples described in FIG. 64;

FIG. 66 shows samples with Substrate: SS-DK180326 (silver, matte+mirror+brush); ML-TiO₂:SS/Al₂O₃ (145)/SiO₂ (100)/TiO₂ (60)/Al₂O₃ (75)/SiO₂ (10);

FIG. 67 shows the plot of reflectance (%) vs wavelength (nm) for samples with ML-TiO₂:SS/Al₂O₃ (145)/SiO₂ (100)/TiO₂ (60)/Al₂O₃ (75)/SiO₂ (10); with matte;

FIG. 68 shows the CIE1931 diagram chromatic coordinates of the samples described in FIG. 67;

FIG. 69 shows the plot of reflectance (%) vs wavelength (nm) for samples with ML-TiO₂:SS/Al₂O₃ (145)/SiO₂ (100)/TiO₂ (60)/Al₂O₃ (75)/SiO₂ (10); with mirror;

FIG. 70 shows the CIE1931 diagram chromatic coordinates of the samples described in FIG. 69;

FIG. 71 shows the plot of reflectance (%) vs wavelength (nm) for samples with ML-TiO₂:SS/Al₂O₃ (145)/SiO₂ (100)/TiO₂ (60)/Al₂O₃ (75)/SiO₂ (10); with brush;

FIG. 72 shows the CIE1931 diagram chromatic coordinates of the samples described in FIG. 71;

FIG. 73 shows the samples with Substrate: SS-DK180326 (silver, matte+mirror+brush); thick Al₂O₃: SS/Al₂O₃ (400×3+400×3+400+200); in ˜3000 nm, 3-day fabrication;

FIG. 74 shows the samples with Substrate: SS-DK180326 (silver, matte+mirror+brush); thick Al₂O₃: SS/Al₂O₃ (400×3+400×3+400+200); in ˜1200 nm, ˜2400 nm and ˜3000 nm;

FIG. 75 shows the plot of reflectance (%) vs wavelength (nm) for samples with thick Al₂O₃: SS/Al₂O₃ (3000);

FIG. 76 shows the CIE1931 diagram chromatic coordinates of the samples described in FIG. 75;

FIG. 77 shows the sample with thick Al₂O₃ coating and ML-TiO₂ at ˜60° and ˜80°:

FIG. 78 shows the samples of stainless steel substrates in silver color with single-layer Al₂O₃ (150 nm); single-layer Al₂O₃ (300 nm); and single-layer Al₂O₃ (450 nm); after #0000 steel wool abrasion; by visual inspection;

FIG. 79 shows the samples of stainless steel substrates in silver color with single-layer Al₂O₃ (150 nm); single-layer Al₂O₃ (300 nm); and single-layer Al₂O₃ (450 nm); after #0000 steel wool abrasion; under optical microscope;

FIG. 80 shows the samples of stainless steel substrates in gold color with single-layer Al₂O₃ (150 nm); single-layer Al₂O₃ (300 nm); and single-layer Al₂O₃ (450 nm); after #0000 steel wool abrasion; by visual inspection;

FIG. 81 shows the samples of stainless steel substrates in gold color with single-layer Al₂O₃ (150 nm); single-layer Al₂O₃ (300 nm); and single-layer Al₂O₃ (450 nm); after #0000 steel wool abrasion; under optical microscope;

FIG. 82 shows the samples of stainless steel substrates in gold color with single-layer Al₂O₃ (700 nm); single-layer Al₂O₃ (1000 nm); single-layer Al₂O₃ (1500 nm) and single-layer Al₂O₃ (2000 nm); after #0000 steel wool abrasion; at DC reactive sputtering;

FIG. 83 shows the samples of stainless steel substrates in rose gold color with single-layer Al₂O₃ (700 nm); single-layer Al₂O₃ (1000 nm); single-layer Al₂O₃ (1500 nm) and single-layer Al₂O₃ (2000 nm); after #0000 steel wool abrasion; at DC reactive sputtering;

FIG. 84 shows the CIE1931 diagram chromatic coordinates for the single Al₂O₃ layer with 450 nm thicknesses on stainless steel substrates (gold color);

FIG. 85 shows the plot of reflectance (%) vs wavelength (nm) for the single Al₂O₃ layer with 450 nm thicknesses on stainless steel substrates (gold color);

FIG. 86 shows the CIE1931 diagram chromatic coordinates for the single Al₂O₃ layer with 700 nm thicknesses on stainless steel substrates (gold color);

FIG. 87 shows the plot of reflectance (%) vs wavelength (nm) for the single Al₂O₃ layer with 700 nm thicknesses on stainless steel substrates (gold color);

FIG. 88 shows the CIE1931 diagram chromatic coordinates for the single Al₂O₃ layer with 1000 mm thicknesses on stainless steel substrates (gold color);

FIG. 89 shows the plot of reflectance (%) vs wavelength (nm) for the single Al₂O₃ layer with 1000 mm thicknesses on stainless steel substrates (gold color);

FIG. 90 shows the CIE1931 diagram chromatic coordinates for the single Al₂O₃ layer with 1500 nm thicknesses on stainless steel substrates (gold color);

FIG. 91 shows the plot of reflectance (%) vs wavelength (nm) for the single Al₂O₃ layer with 1500 nm thicknesses on stainless steel substrates (gold color).

FIG. 92 shows the CIE1931 diagram chromatic coordinates for the single Al₂O₃ layer with 2000 nm thicknesses on stainless steel substrates (gold color);

FIG. 93 shows the plot of reflectance (%) vs wavelength (nm) for the single Al₂O₃ layer with 2000 nm thicknesses on stainless steel substrates (gold color);

FIG. 94 shows the optical reflectance for the single Al₂O₃ layer with different thicknesses stainless steel substrates (gold color).

FIG. 95 shows the color measurement for the single Al₂O₃ layer with different thicknesses stainless steel substrates (gold color);

FIG. 96 shows the optical reflectance for the single Al₂O₃ layer with different thicknesses stainless steel substrates (rose gold color);

FIG. 97 shows the color measurement for the single Al₂O₃ layer with different thicknesses stainless steel substrates (rose gold color);

FIG. 98 shows the samples of single-layer Al₂O₃ (700 nm); single-layer Al₂O₃ (1000 nm); single-layer Al₂O₃ (1500 nm) and single-layer Al₂O₃ (2000 nm); on copper substrates (rose gold color) after #0000 steel wool abrasion 100 cycles; abrasion loading on Cu substrate is 500 g;

FIG. 99 shows the samples of single-layer Al₂O₃ (700 nm); single-layer Al₂O₃ (1000 nm); single-layer Al₂O₃ (1500 nm) and single-layer Al₂O₃ (2000 nm); on copper substrates (rose gold color) after #0000 steel wool abrasion 400 cycles; abrasion loading on Cu substrate is 500 g;

FIG. 100 shows the optical reflectance for single Al₂O₃ layer with different thickness on copper substrates (rose gold color);

FIG. 101 shows the simulation results for single Al₂O₃ layer with different thickness on copper substrates (rose gold color);

### DETAILED DESCRIPTION

The present invention provides composite single or multilayer thin films on various metal substrates. The metal substrates may include a variety of colors, thicknesses and finishes. The composite thin films demonstrate good abrasion resistance and excellent adhesion between the thin films and metal substrates. In one aspect, the present invention maintains a metallic appearance and color consistent with a bare metal substrate. The present invention also provides two different coating systems for a composite thin film and a method of manufacturing a composite thin film on different metal substrates.

In one aspect, the present invention provides a coating on a metal substrate that includes at least four layers. The layers are:
1) The first layer (from the metal substrate) comprises Al₂O₃, and has a thickness of approximately 100˜150 nm, with a refractive index is approximately 1.7;
2) The second layer (from the metal substrate) comprises SiO₂ and has a thickness of approximately 80˜120 nm, with a refractive index is about 1.4;
3) The third layer (from the metal substrate) comprises TiO₂ with a thickness of approximately 50˜80 nm with a refractive index of approximately 2.2;
4) The fourth layer (from the metal substrate) comprises Al₂O₃ with a thickness of approximately 60˜90 nm;
Optionally, a top layer/fifth layer can be provided that includes (SiO₂) with a thickness of approximately 10˜20 nm.
A total thickness of the combined layers for a four-layer structure is approximately: 280-400 nm. If there are more than four layers, the total film thickness may be over 400 nm.

In a particular embodiment, the present invention provides (1) a structure including of Al₂O₃ (sapphire), SiO₂, ZrO₂/TiO₂; (2) a 4-layer structure: Al₂O₃ (with thickness of approximately 145 nm)/SiO₂ (with a thickness of approximately 100 nm)/TiO₂ (with a thickness of approximately 60 nm)/Al₂O₃ (with a thickness of approximately 75 nm)+SiO₂ (with a thickness of approximately 10 nm) where TiO₂ can be replaced by ZrO₂ structure and at least 4-layer structure by using SiO₂/TiO₂.

In another aspect, the present invention provides a sapphire (Al₂O₃) coating on a metal substrate. The coating may have a thickness in a range of up to approximately 1500-2000 nm and a refractive index of about 1.7.

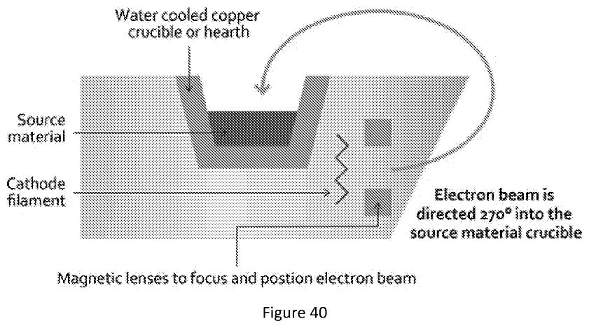

The various layers of the present invention may be deposited with an electron beam evaporation system or a sputtering system. EB (electron beam) evaporation is a thermal evaporation process, and, along with sputtering, is one of the two most common types of physical vapor deposition (PVD). EB evaporation provides for the direct transfer of a larger amount of energy into the source material, enabling the evaporation of metal and dielectric materials with very high melting temperatures, such as gold and silicon dioxide, respectively. Therefore, it is possible to deposit materials that cannot be evaporated with standard resistive thermal evaporation. An additional benefit of e-beam evaporation is higher deposition rates than possible with either sputtering or resistive evaporation. A schematic diagram of an EB system that may be used in the present invention is shown in FIG. 40.

In EB evaporation, the evaporation material can be placed directly in a water-cooled copper hearth or into a crucible and heated by a focused electron beam. The heat from the electron beam vaporizes the material, which then deposits on the substrate to form the required thin film. FIG. 40 shows the operating schematics of the EB evaporation system.

Sputtering is a deposition technology involving a gaseous plasma which is generated and confined to a space containing the material to be deposited—the ‘target’. The surface of the target is eroded by high-energy ions within the plasma, and the liberated atoms travel through the vacuum environment and deposit onto a substrate to form a thin film.

The evaporation and sputtering may use oxide materials as the targets to directly deposit the oxides. Alternatively, metal targets may be used in an oxygen-containing atmosphere for reactive evaporation or reactive sputtering. Further, a single system may be provided with both electron beam evaporation capabilities and sputtering capabilities such that each layer may be fabricated independently by evaporation or by sputtering. Vacuum conditions are maintained between deposition of the sequential layers on the substrate, ensuring that no contamination of the layer surfaces occurs between adjacent depositions. This ensures strong inter-layer bonding as well as strong substrate adhesion.

In particular, the deposition of the layers of the present invention may be performed without any heating or cooling applied to the substrate, to the electron beam or sputtering targets, to the deposition system. Further, no post-deposition annealing of the multilayer thin film structure is required

Five exemplary thin film structures are described below as examples of the coating deposited on metal substrates. The first four structures were fabricated using an electron beam evaporation system while the fifth embodiment was fabricated using a sputtering system. The coatings enhance the metal substrate appearance and provide a perceived color consistent with that of the bare metal substrate. The coating also improves abrasion resistance for the metal substrate.

An optional top layer/fifth layer includes SiO₂ with an approximately 10 nm thickness “SiO₂ (10)” and Anti-fingerprint (AF) material coated on all the top structure (layer number without considering the optional SiO₂ plus AF layers, anti-fingerprint material), which can improve the metal substrate sample abrasion resistance and has no influence on substrate color.

A variety of materials may be used as the anti-fingerprint material. In one embodiment, oleophilic polymer coatings may be used. In one aspect, the oleophilic polymers may be fluorinated polymers. An example of such a coating is SURECO AF, a fluorinated polyether available from AGC Chemicals. Other commercially-available fluorochemical coatings from Daikin, (such as OPTOOL, an anti-smudge coating) may also be used. Further anti-fingerprint coatings are commercially available from Aculon and 3M and may be used in the present invention.

Another type of AF coating are fluorinated materials that can be bonded with organometallic coatings as described in U.S. Pat. Nos. 8,236,426 and 8,067,103 the disclosures of which is incorporated by reference herein. Organosilicon material-based nanocoatings may also be used such as those disclosed in CN105255301A, the disclosure of which is incorporated by reference herein. In another aspect, a combination of SiO₂ and sputtered CaF2 may be used as AF coatings, such as disclosed in CN102443763B, the disclosure of which is incorporated by reference herein.

The various embodiments of the present invention are demonstrated on a variety of stainless steel substrates. Stainless steel was selected as this material is used in a variety of consumer and commercial products, including home appliances, industrial equipment, and transportation systems. However, it is understood that the present invention may be applied to other metal substrates, including, but not limited to, steel, aluminum, titanium, copper, nickel, chrome, and tin.

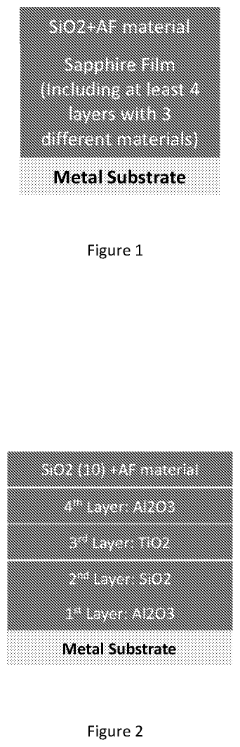

FIG. 1 and FIG. 2 depict the overall structure of the multilayer thin film structure, with an optional topcoat layer. Table 1 shows the material thickness and refractive index of each layer:

TABLE 1
Material property and requirement:

| | Material Density | | |
|---|---|---|---|
| | (GM/CC: gram per | | Refractive |
| | cubic centimeter) | Z-Value | Index |
| Al₂O₃ | 3.97 | 0.336 | 1.6~1.8 |
| SiO₂ | 2.65 | 1 | 1.35~1.5 |
| TiO₂ | 4.26 | 0.4 | 2.7~2.85 |
| ZrO₂ | 5.6 | 1 | 2.1~2.3 |

The Z-value is also called Z ratio or Z factor. It is used to match the acoustic properties of the material being deposited to the acoustic properties of a base quartz material of a sensor crystal.

FIG. 2 depicts a more specific embodiment of the present invention, the thickness range used for the embodiment in FIG. 2 are:
The first layer thickness is approximately 100˜150 nm;
The second layer thickness is approximately 80˜120 nm;
The third layer thickness is approximately 50˜80 nm;
The fourth layer thickness is approximately 60˜90 nm;
The optional top layer thickness is approximately 10˜20 nm.

As used herein, the term “approximately” generally includes values of plus or minus 10 percent and, in some cases, values of plus or minus 20 percent when the properties of the overall layer structure are not adversely affected in terms of adhesion, color, and abrasion-resistance.

### Structure Explanation:

Comparative structures to those of the present invention are 1-layer, 2-layer, structure and a 5-layer fabricated entirely by an electron beam system.

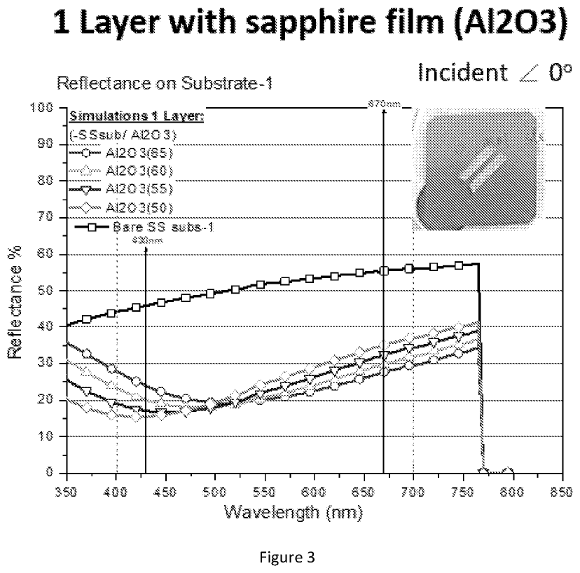

For a single layer of Al₂O₃, it was determined that compared to an uncoated substrate, the simulated reflectance for a single layer (sapphire-Al₂O₃) is not consistent. These results are shown in FIG. 3.

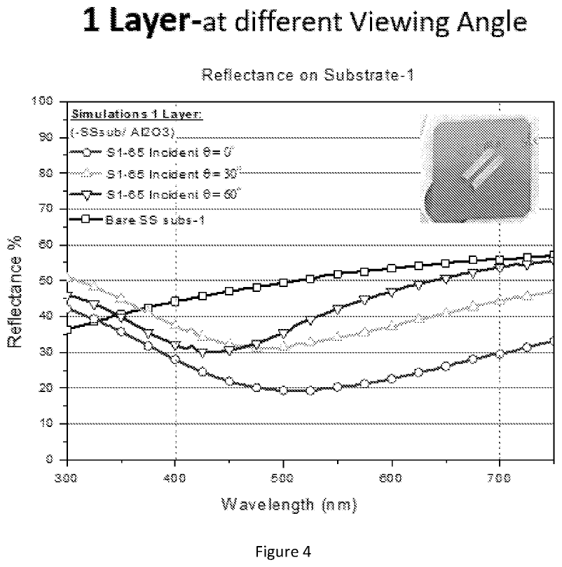

For a single layer of Al₂O₃, the findings are that compared to an uncoated substrate, the simulated reflectance for different viewing angles for a single layer (sapphire-Al₂O₃) is not consistent. This problem persists for larger Al₂O₃ thicknesses and for other single layers of material These findings are shown in FIG. 4. Consequently, it was determined that a multi-layer structure is required in order to obtain the desired appearance of the underlying substrate metal.

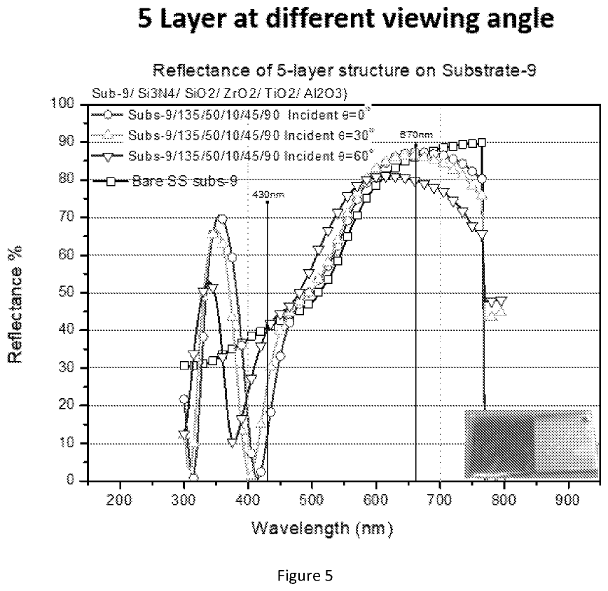

For an embodiment of the present invention, the 5-layer structure reflectance for a viewing angle of +/−60° is obviously different to reflectance of the bare substrate and of 5-layer structure when the viewing angles are 0°, 30°. These findings are shown in FIG. 5.

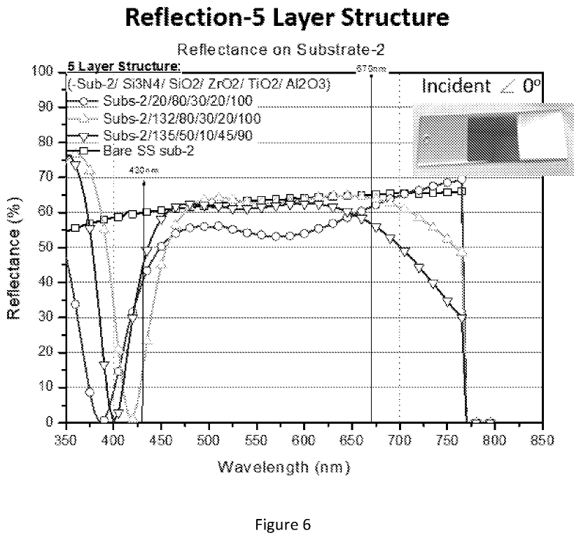

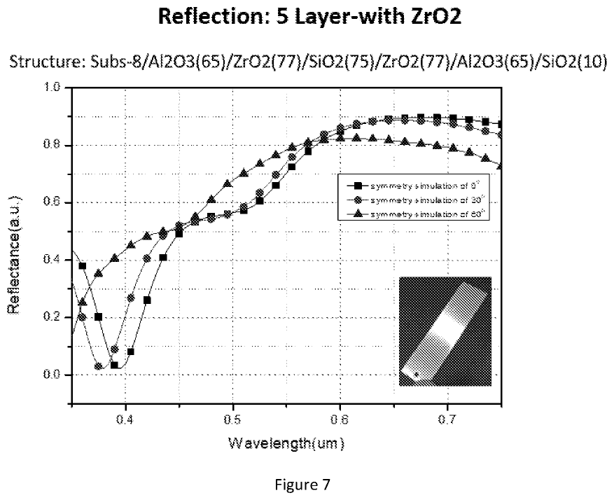

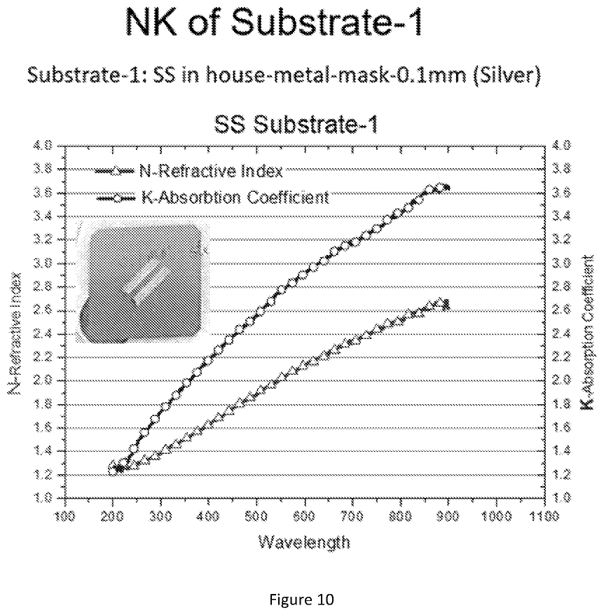

In one embodiment of the present invention, the multi-layer structure having the best color properties is one that has least four layers (24). As shown above, structures with fewer than four layers is not ideal for the color requirement of being able to view the color of the base metal. Further, it was determined that a four-layer structure-Al₂O₃ (145)/SiO₂ (100)/TiO₂ (160)/Al₂O₃ (75) present good reflectance/color consistence, good abrasion resistance and have been verified on four different metal substrates-1, 2, 3, 4, which are specifically described in the four embodiments shown in Example-1, 2, 3, 4 (FIGS. 10 to 39). For the comparative structure of 1 layer, and 5 layers (without consideration for the optional top layers of SiO₂ and AF coating), structures were as follows:
Layer Structure (FIG. 3): Substrate-1/Al₂O₃ (50-65 nm),
5-layer Structure (FIG. 5, FIG. 6):
Substrate-9/Si₃N₄ (135)/SiO₂ (50)/ZrO₂ (10)/TiO₂ (45)/Al₂O₃ (90)
Substrate-2/Si₃N₄ (20)/SiO₂ (80)/ZrO₂ (30)/TIO, (20)/Al₂O₃ (100)
Substrate-2/Si₃N₄ (132)/SiO₂ (80)/ZrO₂ (30)/TiO₂ (20)/Al₂O₃ (100)
Substrate-2/Si₃N₄ (135)/SiO₂ (50)/ZrO₂ (10)/TiO₂ (45)/Al₂O₃ (90)

The optional top layer includes SiO₂ (10) (thickness 10 nm), as a buffer layer between an AF material and the lower 4 layers. The optional top layers of SiO₂ (10)+AF coating can increase sample abrasion resistance and have no influence on sample appearance and color. The specific influence of SiO₂ (10)+AF coating is on following

### Influence of SiO₂ (10)+AF Coating

Table 2 shows the comparison for 4-layer structure Al₂O₃
(145)/SiO₂ (100)/TiO₂ (160)/Al₂O₃ (75) with and without SiO₂ + AF coating.

| | | |
|---|---|---|
| Samples tested | Appearance after T1 test | Appearance after T2 test |
| | Load: 1 kg | Load: 250 g |
| | Contact area: 10 × 10 mm² | Contact area: 10 × 10 mm² |
| | Speed: 60 cpm | Speed: 60 cpm |
| | Cycles: 100 | Cycles: 100 |
| Sample-1-1: 4-Layer | Serious scratch mark | Light scratch mark |
| Sample-1-1: 4-Layer + SiO₂ + AF | Very light scratch mark | No scratch mark |

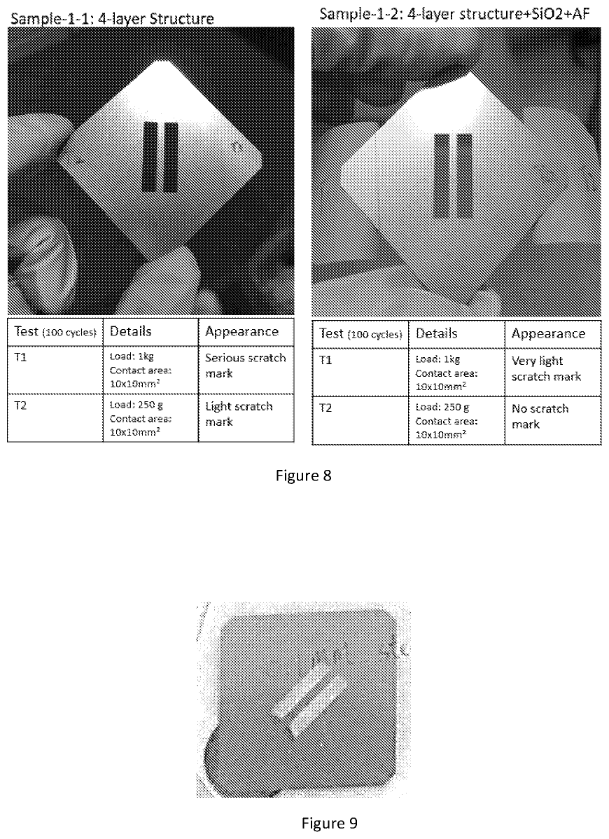

According to FIG. 8 and Table 2, it indicates that SiO₂ (10)+AF coating can obviously increase sample abrasion resistance and have no influence on sample appearance color.

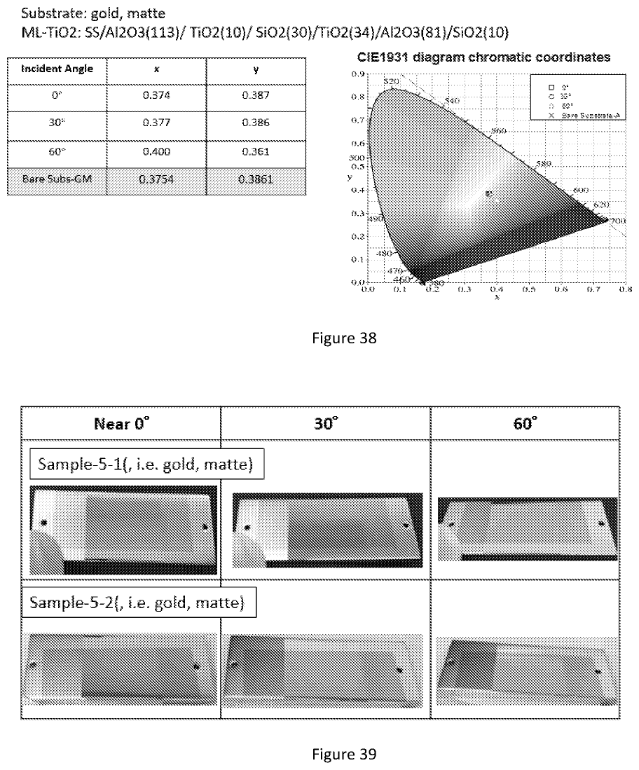

The present invention including the protection on the isotope of Zr (in 3^{rd} layer for 5-layer structure), Ti (in 3^{rd} layer for 4-layer structure) and Si (in 2^{nd} layer for 4-layer structure). For samples fabricated by EB system, the embodiments of the present invention mainly focus on viewing angle-0°. The fifth example (FIG. 38) fabricated by sputtering system presents better color consistency on different viewing angle.

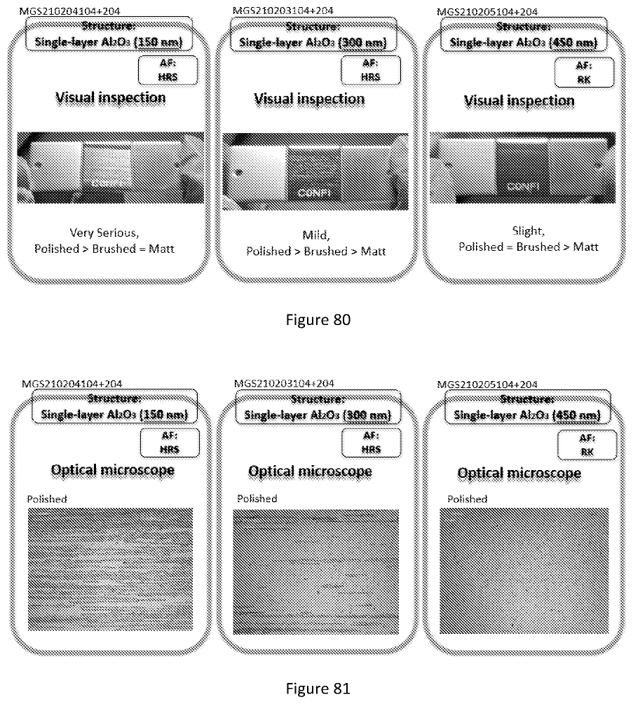

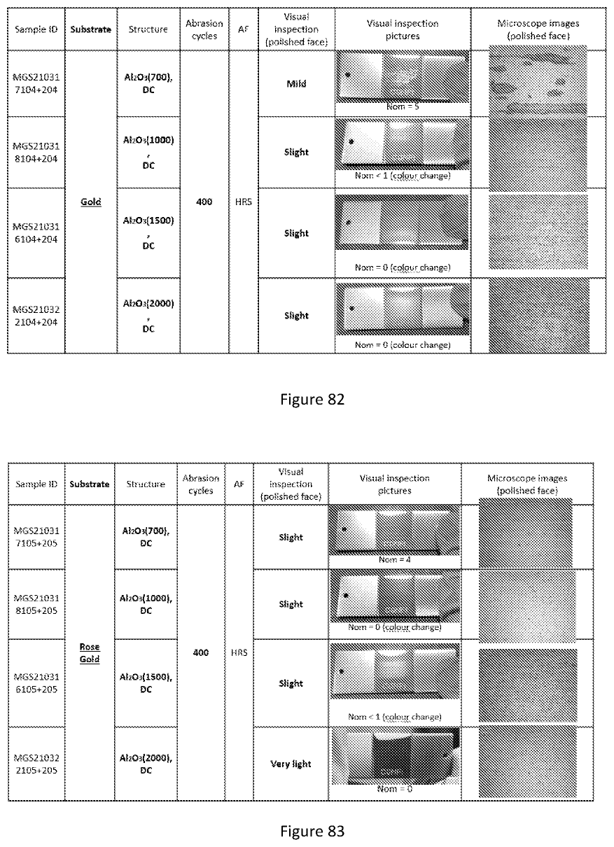

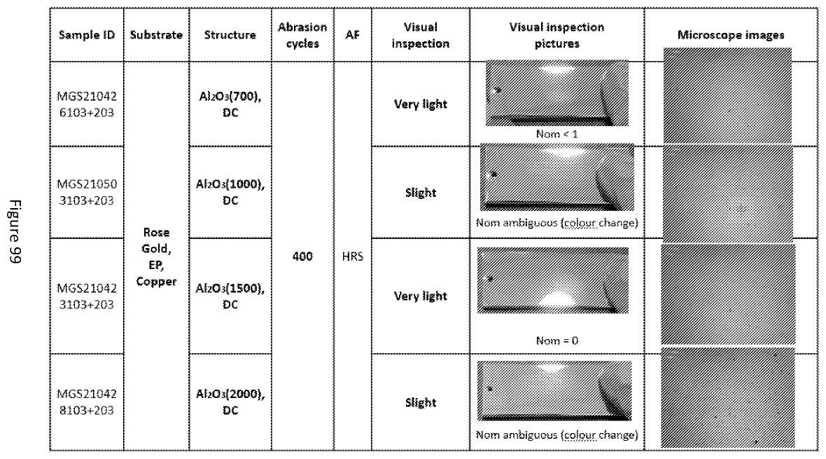

In another aspect, the present invention provides an anti-abrasion protective thin film structure deposited on a metal substrate by sputtering. A metal substrate, such as a stainless steel substrate, is provided. At least a first layer is positioned on a surface of the metal substrate; the first layer comprises Al₂O₃ with a thickness up to 2000 nm and a refractive index of about 1.7. An optional second layer including SiO₂ layer may be positioned on a surface of the first layer comprising Al₂O₃. Alternatively, an anti-fingerprint coating may be positioned on the surface of the first layer comprising Al₂O₃ or on the second layer including SiO₂. Examples of these sputtered films may be found in FIGS. 80-90 and 98-101.

Various phases of Al₂O₃ may be used in the sputter-deposited layer, including sapphire and sapphire mixtures.

### EXAMPLES

### Example-1: Substrate-1: SS in House-Metal-Mask-0.1 mm (Silver)

FIG. 10 shows the property (N-refractive index, K-absorption coefficient) of substrate-1, wherein NK curve indicates unique property of the metal substrate. Substrate means bare substrate without coating on surface; sample means substrate coated with thin film. Sample-1 means substrate-1 with coating on surface.

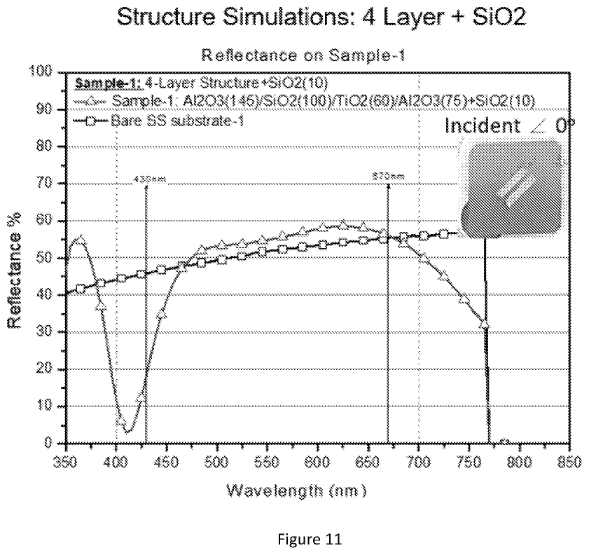

FIG. 11 shows the reflectance comparison for sample-1 and bare substrate-1, wherein the reflectance curve for sample with thin film is consistent with bare metal substrate on visible light wavelength (470˜670 nm). Reflectance consistency will make the sample appearance color be the same as the bare metal substrate.

### 3) Sample-1: Abrasion Testing Result

Sample 1-1: 4-Layer Structure: Al₂O₃ (145)/SiO₂ (100)/TiO₂ (60)/Al₂O₃ (75)+SiO₂ (10)+AF.

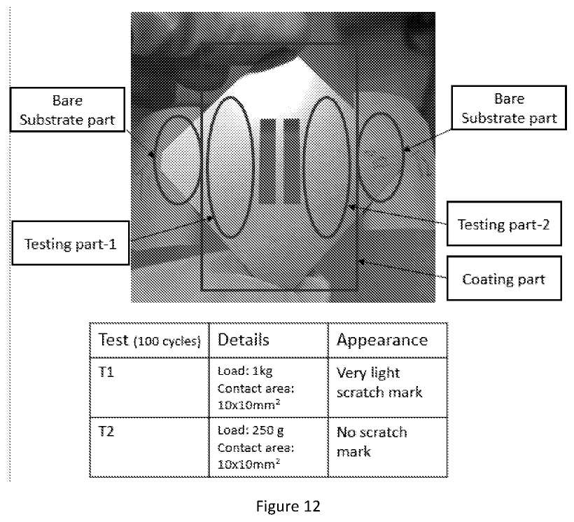

FIG. 12 shows abrasion testing of sample-1, wherein the color testing can refer to the following-explanation of color testing

### Explanation for Color Testing

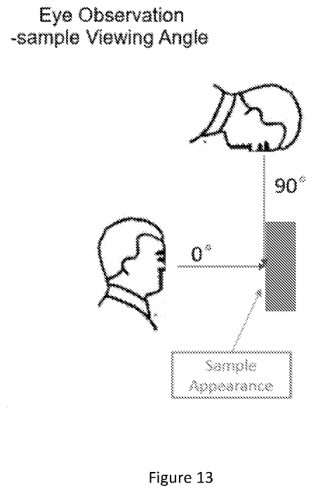

Color testing is done via eye observation and optical testing as illustrated in FIG. 13.

### Analysis for Sample Color

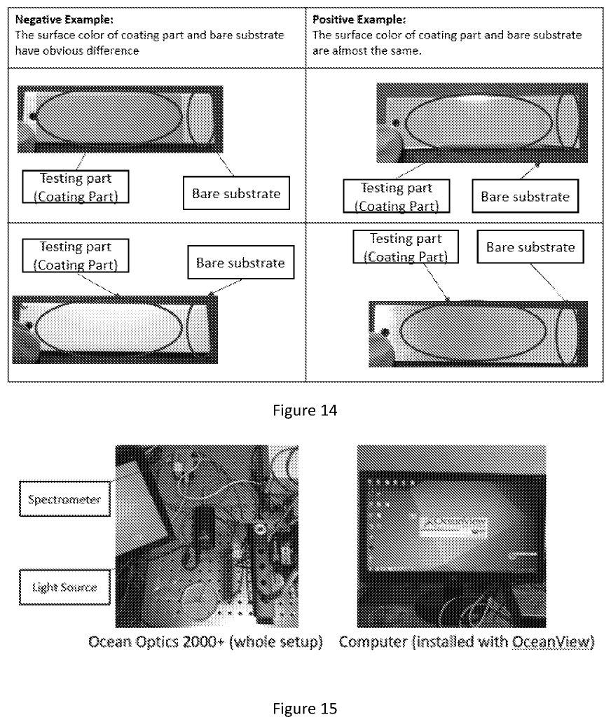

FIG. 14 shows sample color examples of two groups (Negative vs Positive).

The negative examples present obvious color difference between bare substrate part and coating part, while the color of bare substrate part and coating part are very consistent.

### Optical Testing:

FIG. 15 shows color testing device (Ocean Optics 2000+) and relative software (Ocean View).

FIG. 16 shows sample stage and parameter set, color testing result in software (Ocean View), wherein the consistency of reflectance curve and the overlay ratio in CIExy graph between sample and bare substrate present the color result. If the two reflectance curves are very consistent or the two points in CIExy graph were covered by each other, then the surface color for sample and bare substrate must be the same. In contrast, if the two reflectance curves of sample and bare substrate are not consistent and the two points in CIExy graph have large distance therebetween, then the reflected color must be obviously different, and this coating or sample will be regarded as failed. Wherein for the analysis and embodiments of the present invention: Sample-1-1 means the first sample with substrate-1, sample-1-2 means the second sample with substrate-1; Sample-1-1 with 4-Layer structure+ SiO₂+AF presents good abrasion resistance (FIG. 8). (Abrasion testing comparison can refer to the following-explanation of abrasion testing.)

### Explanation for Abrasion Testing—(Equals to Steel Wool #0000 Testing)

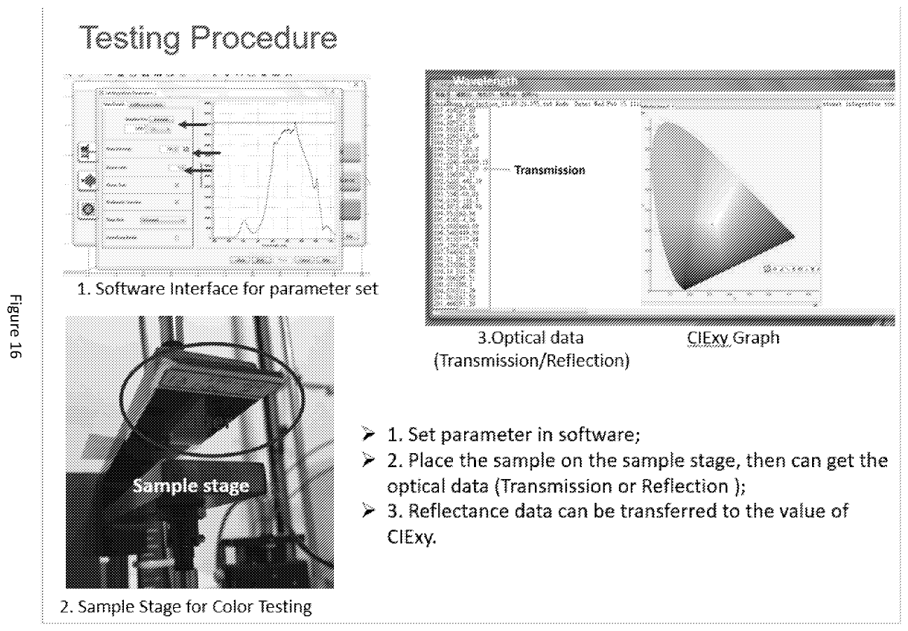

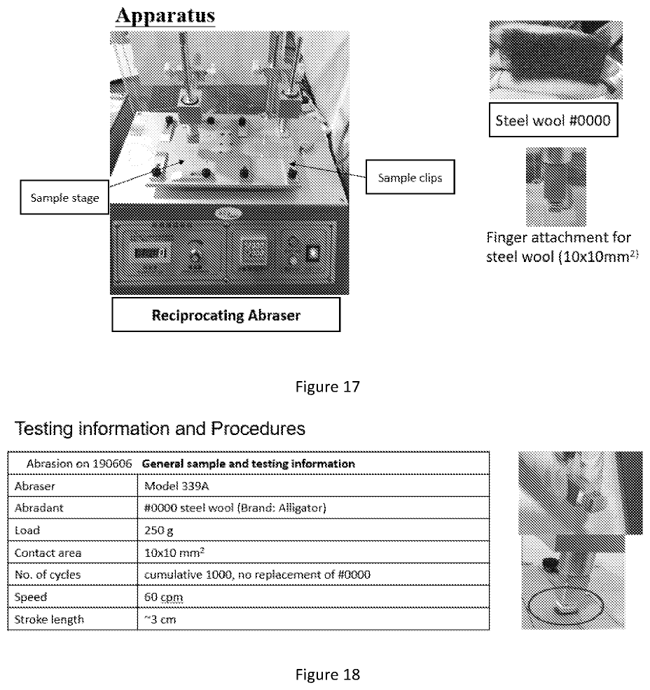

FIG. 17 shows device and steel wool for abrasion testing. The testing information and procedures are as shown in FIG. 18.

### Steel Wool Testing Procedures:

For embodiments of the present invention, the steel wool testing procedures are as follow: 1. Turn on the power of tester and set the testing parameter; 2. To prevent the steel wool slipping away during the test, bound a translucent rubber to the contact area of the finger attachment by a rubber band. The translucent rubber should be just able to cover the contact area. 3. The steel wool (orientation of the steel wool fibers along the abrasion back and forth direction) should be placed between the sample surface and the square finger attachment. 4. Place the sample and secure the sample using the clips on the sample stage. 5. Set testing parameter (SS testing parameter listed on the top table) and start testing.

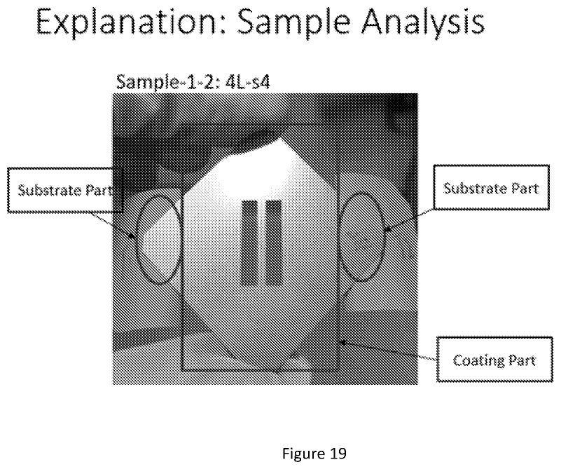

FIG. 19 shows a sample photo for sample analysis (Color & Abrasion Resistance), wherein_Substrate Part means bare substrate without any coating on surface; Coating Part means substrate coated with thin film.

Furthermore, analyzation of sample from two aspects (the same with aim of this project): Color: Trying to keep the surface color for substrate part and the coating part the same. Abrasion Resistance: Avoid scratch on sample appearance after steel wool testing.

Meanwhile, the sample surface color is almost the same with bare metal substrate.

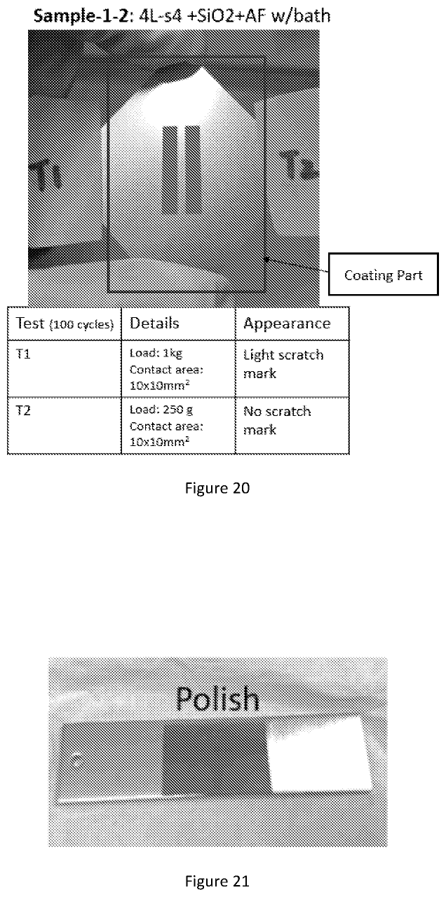

FIG. 20 shows the photo of sample-1-2, wherein Sample-1-2 with 4-layer structure+SiO₂+AF with bath presents good abrasion resistance. Meanwhile, sample surface color is almost the same with bare metal substrate. This sample coated the same structure on substrate-1. According to the FIG. 20, sample surface color is the same with sample-1-1 and bare substrate. Also, it presented good abrasion resistance. Sample-1-1 and sample-1-2 means the same substrate and structure coated on different date, which can verify the repeatability of designed structure for sample color and abrasion resistance.

TABLE 3
Summary for In-house SS substrate-1

| | | |
|---|---|---|
| Samples tested | Appearance after T1 test | Appearance after T2 test |
| | Load: 1 kg | Load: 250 g |
| | Contact area: 10 × 10 mm² | Contact area: 10 × 10 mm² |
| | Speed: 60 cpm | Speed: 60 cpm |
| | Cycles: 100 | Cycles: 100 |
| Bare SS sub | Mild scratch mark | No scratch mark |
| Sample-1-1&2: | Very light/light scratch mark | No scratch mark |
| 4L-s4#4 + SiO₂ + AF | | |

### According to Sample Testing Results:

1. Reflectance curve of sample is consistent to bare metal substrate on visible wavelength range, and sample appearance color look almost the same with bare substrate-1 at normal viewing or vertical viewing.

After 4-layer structure Al₂O₃ (145)/SiO₂ (100)/TiO₂ (60)/Al₂O₃ (75), coated and with AF coating, sample abrasion resistance has obviously been improved. For Test 1 (T1) testing, only light scratch mark on sample appearance. And for Test 2 (T2) testing, there is no scratch mark.

### Example-2: Substrate 2: SS-DK180403S, Polish

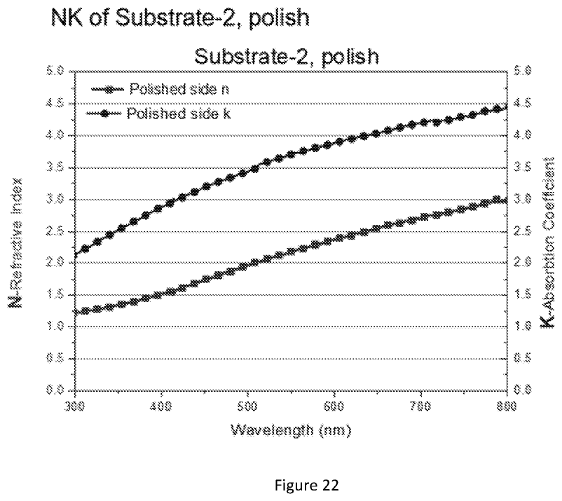

While FIG. 21 shows a photo of substrate-2, FIG. 22 shows the property (N-refractive index, K-absorption coefficient) of substrate-2, wherein this substrate includes three different parts, so presents three different NK Curves. The property mainly refers to the polished portion of substrate-2.

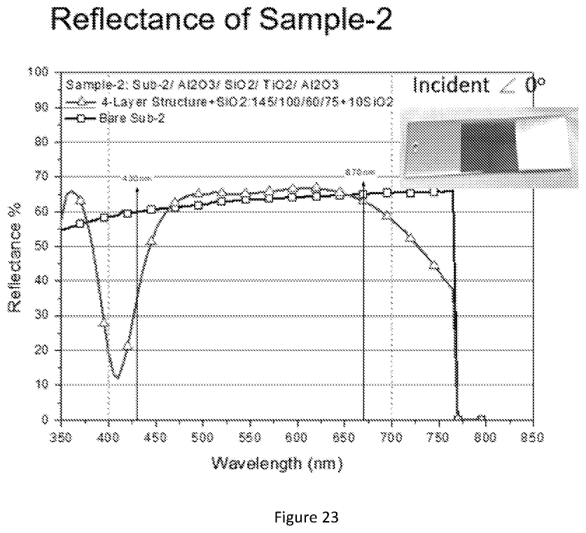

FIG. 23 shows the reflectance comparison for sample-2 and bare substrate-2.

FIG. 23 shows the reflectance comparison for sample-2 and bare substrate-2, wherein the reflectance curve for the sample with a thin film coating is consistent with bare metal substrate on visible light wavelength.

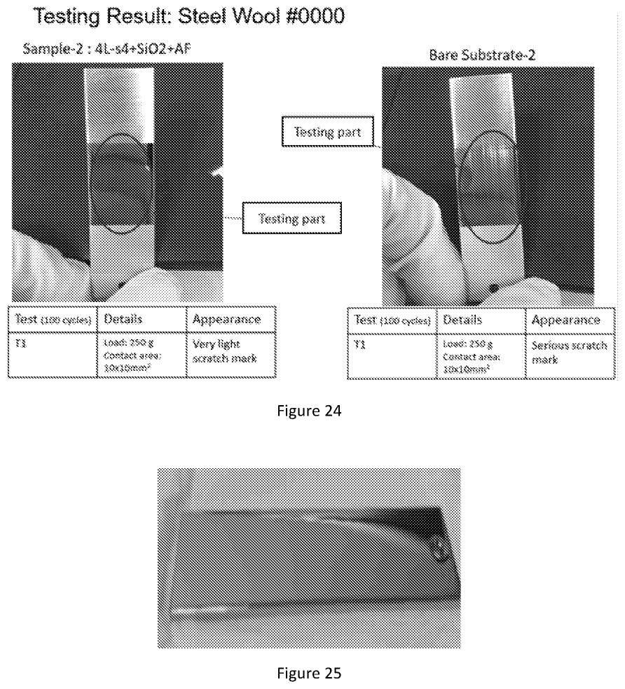

FIG. 24 shows the comparison of abrasion testing between bare substrate-2 and Sample-2, wherein according to Steel wood #0000 testing result, substrate-2 with 4-Layer Structure+SiO₂ present better abrasion resistance. Also, the reflectance curve of sample is consistent to bare metal substrate on visible wavelength range, sample appearance has no obvious color change compared with bare substrate-2.

TABLE 4
Steel wool #0000 on substrate-2 [Summary]

| | |
|---|---|
| Samples tested | Appearance after T1 test |
| | Load: 250 g |
| | Contact area: 10 × 10 mm² |
| | Speed: 60 cpm |
| | Cycles: 100 |
| Bare SS sub | Serious scratch mark |
| 4L-s4 + SiO₂ + AF | Very light scratch mark/ |
| | Mild scratch mark |

### Example-3: Substrate-3: Rose Gold-SS, Mirror

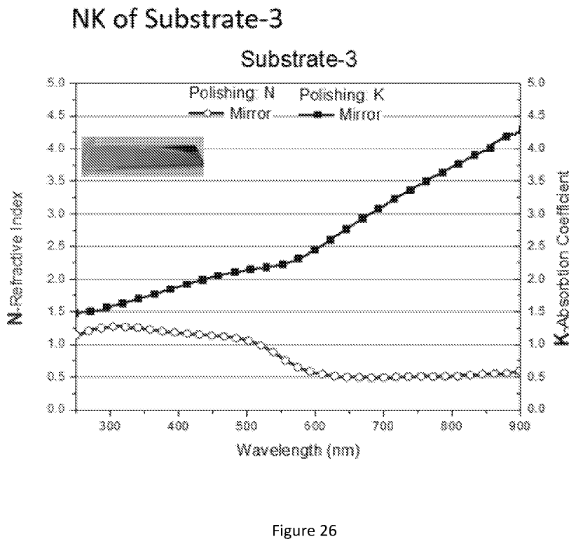

FIG. 25 shows a photo of substrate-3 and FIG. 26 shows the property (N-refractive index, K-absorption coefficient) of substrate-3, wherein rose gold SS substrate includes three different types. Each presents better properties with the coating of the present invention.

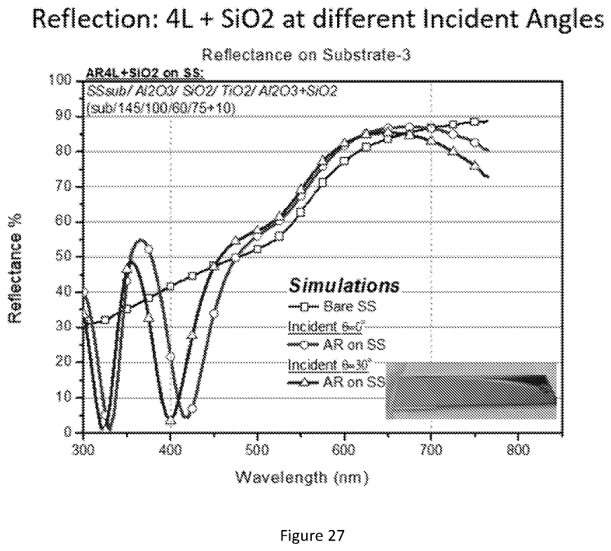

FIG. 27 shows the reflectance comparison of sample-3 in different viewing angle (0°, 30°) and bare substrate-3. It is observed that it is easy to color shift when observe samples on different viewing angle. The reflectance curve of sample is consistent with the bare metal substrate in the visible wavelength range, sample appearance has no obvious color change compared with bare substrate-3. The reflectance curve maintains ideal consistence with bare substrate-3, even when viewing angle reaches to 30°.

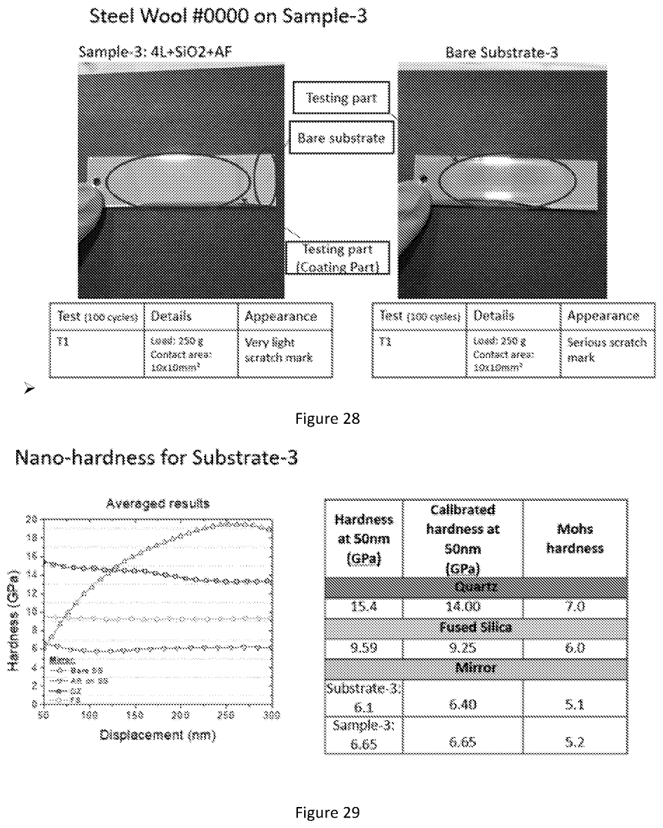

FIG. 28 shows the comparison of abrasion testing between bare substrate-3 and Sample-3, wherein compared with testing part of Sample-3 (with 4-layer coating) and bare substrate (without coating) after steel wool #0000 testing result, sample-3 (substrate-3 with 4-Layer structure+SiO₂ & AF material) presents better abrasion resistance. Also, for sample-3, surface color of coating pare and bare substrate part are almost the same.

FIG. 29 shows the nano-hardness of bare substrate-3 and sample-3, wherein the nano-hardness of Quartz and Fused Silica (FS) are the benchmark samples, only when testing results of benchmark samples are right (Quartz-14, FS-9.25), the testing results for other samples can be regarded as reliable. For substrate-3, Sample with 4-layer structure presents higher nano-hardness.

### Example-4: Substrate-4: Rose Gold-SS, Brush (RB)

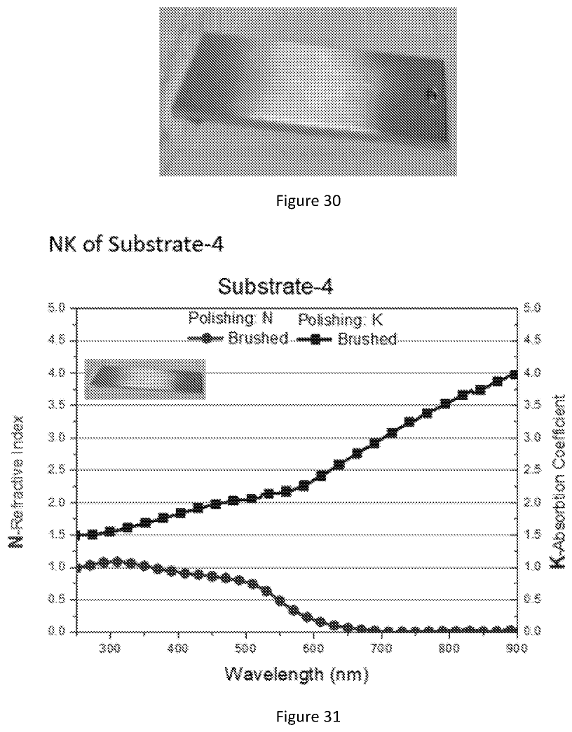

FIG. 30 shows a photo of substrate-4 and FIG. 31 shows the property (N-refractive index, K-absorption coefficient) of substrate-4, wherein rose gold SS substrate includes three different types. Each presents better property with 4-layer structure-Al₂O₃ (145)/SiO₂ (100)/TiO₂ (60)/Al₂O₃ (75)/SiO₂ (10).

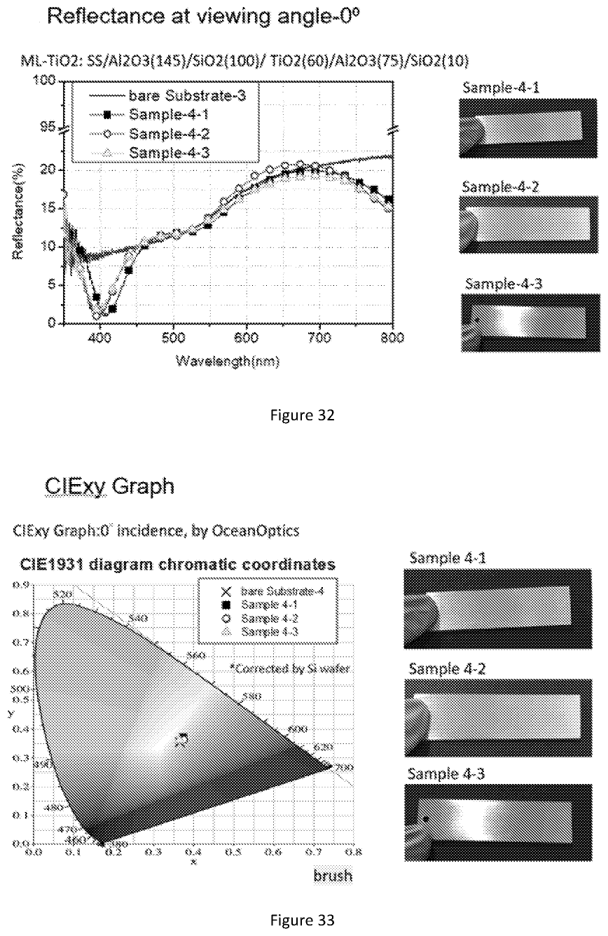

FIG. 32 shows the reflectance comparison of sample-4 (three samples of the same substrate and structure) and bare substrate-3, wherein it is observed that there is ideal consistency between bare substrate and samples (Coated with thin film), and structure repeatability is ideal.

In one embodiment of the present invention, as shown in FIG. 33, it can be seen that the color results present ideal repeatability and consistency for sample-4 color, wherein related samples present good color consistency according to CIExy.

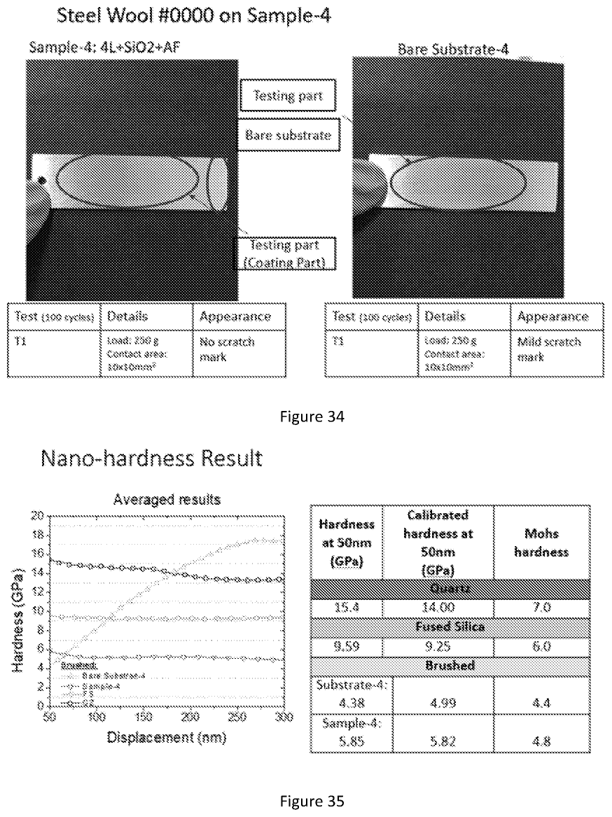

FIG. 34 shows the comparison of abrasion testing between bare substrate-4 and Sample-4, wherein compared with testing part of Sample-4 (with 4-layer coating) and bare substrate (without coating) after abrasion testing result, sample-4 (substrate-4 with 4L+SiO₂) present better abrasion resistance. Also, for sample-4, surface color of coated sample and bare substrate part are almost the same. As shown in FIG. 35, for substrate-4, Sample with S4 structure presents higher nano-hardness.

### Example-5: Substrate-5: SS-Gold Matte (GM)

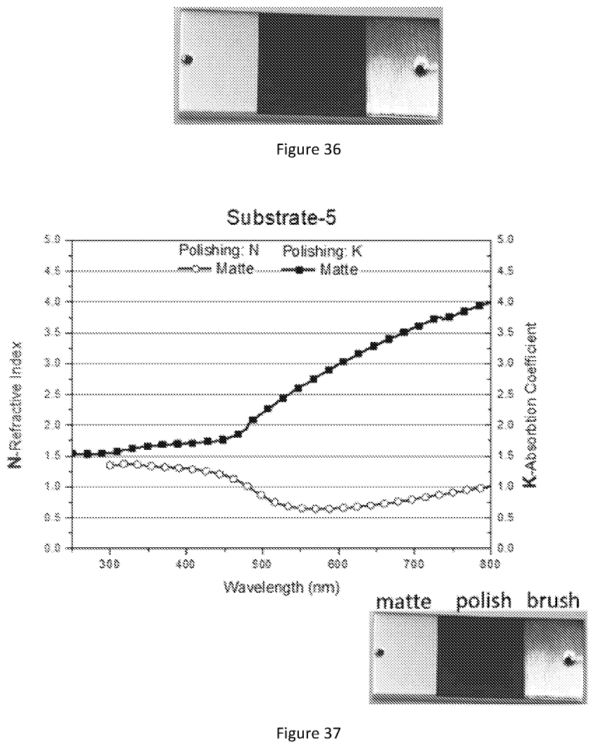

FIG. 36 shows a photo of substrate-5 which is fabricated using a sputtering deposition system and FIG. 37 shows the property (N-refractive index, K-absorption coefficient) of substrate-5.

### CIExy of Sample-5

FIG. 38 shows the color comparison of Sample-5 and Substrate-5 in CIExy graph, wherein sample CIExy for appearance color (0° and 30°) is the same with bare substrate. Only when viewing angle reaches 60°, CIExy shifts a little. This is also almost the best color consistency compared with previous samples. The simulation result (FIG. 38) is consistent with fabricated samples. The structure is mainly designed for matte part, and the coating result presents that it can also be used on polish and brush part of the substrate.

FIG. 39 shows the photos of Sample-5 in different viewing angle (0°, 30°, 60°), wherein from the comparison between sample-5-1 and sample-5-2, consistency and color match for current structure are ideal.

TABLE 6
Results for FIG. 44

| | |
|---|---|
| | WCA (°) |
| No. of | SS190815201 |

| cycles | Polished | Brush |
|---|---|---|
| 0 | 115.2 ± 1.6 | 116.0 ± 1.5 |
| 100 × 1 | 93.2 ± 3.6 | 97.5 ± 1.3 |

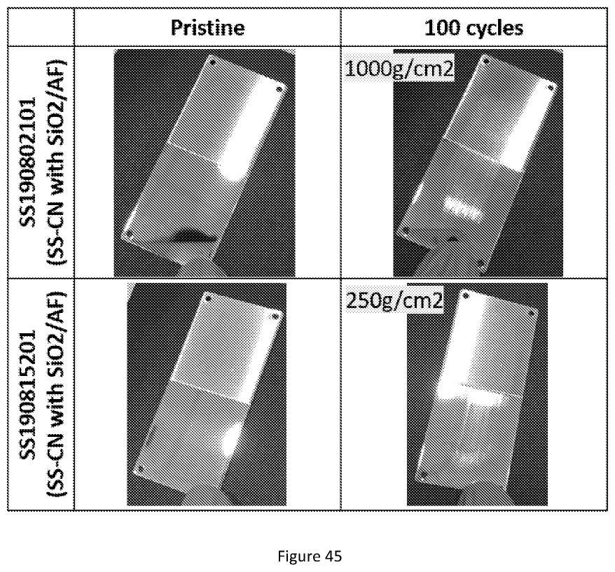

TABLE 7
Results for FIG. 45, sample SS190802101

| | |
|---|---|
| No. of | Water Contact Angle “WCA (°)” |
| cycles | SS190802101 |

| (1000 g) | Polished | Brush |
|---|---|---|
| 0 | 116.8 ± 1.6 | 116.9 ± 1.7 |
| 100 × 1 | 84.2 ± 4.3 | 85.7 ± 5.2 |

TABLE 8
Results for FIG. 45, sample SS190815201

| | |
|---|---|
| No. of | WCA (°) |
| cycles | SS190815201 |

| (250 g) | Polished | Brush |
|---|---|---|
| 0 | 115.2 ± 1.6 | 116.0 ± 1.5 |
| 100 × 1 | 93.2 ± 3.6 | 97.5 ± 1.3 |

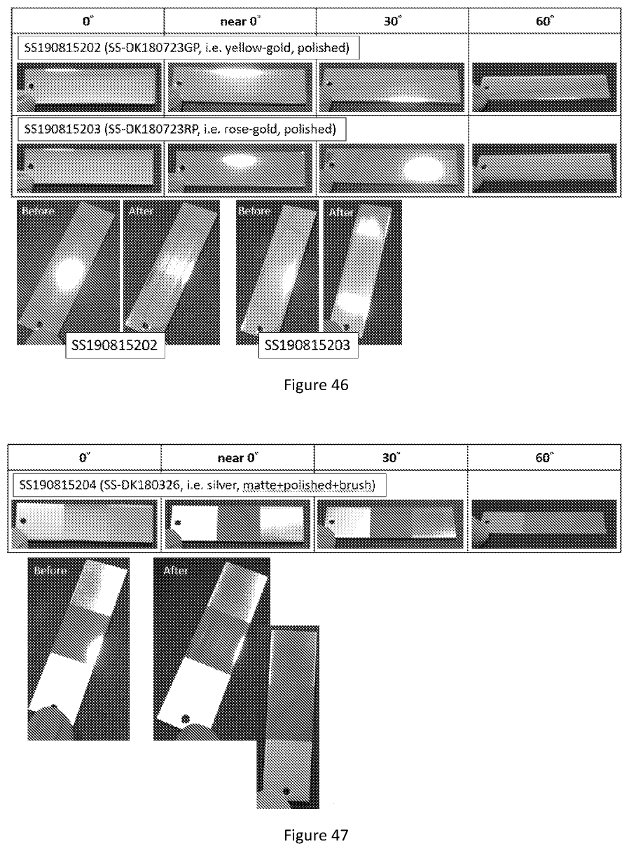

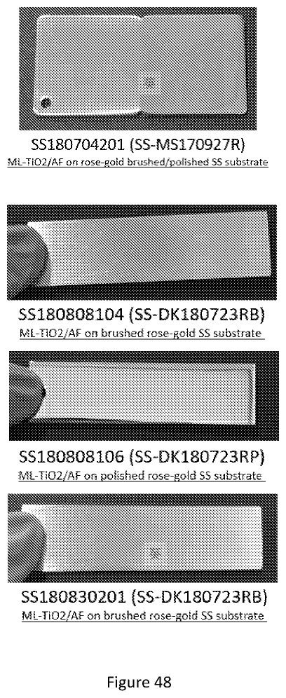

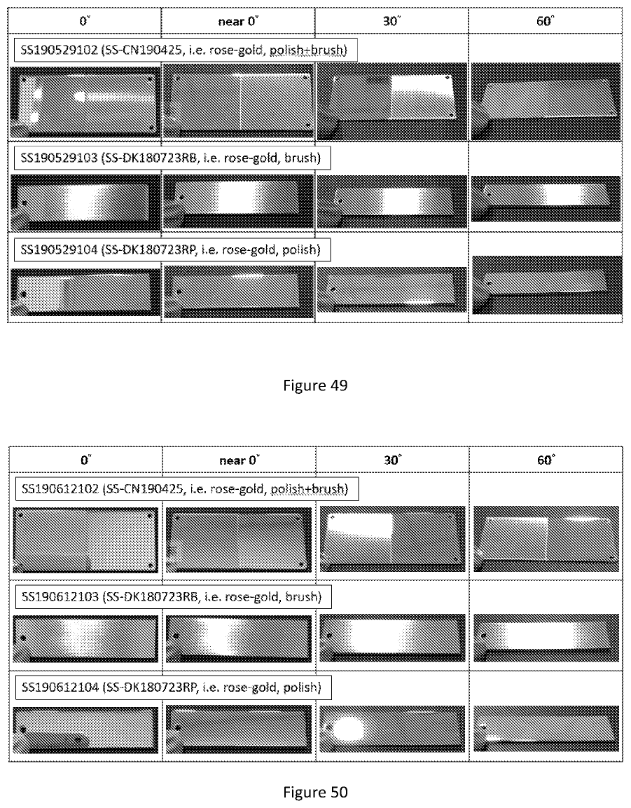

TABLE 9
Results for FIG. 46

| | |
|---|---|
| No. of | WCA (°) |

| cycles | SS190815202 | SS190815203 |
|---|---|---|
| 0 | 114.2 ± 1.9 | 117.6 ± 2.0 |
| 100 × 1 | 90.3 ± 1.3 | 85.7 ± 4.5 |

TABLE 10
Results for FIG. 47

| | WCA (°) | | |
|---|---|---|---|
| No. of | SS190815204 | | |
| cycles | Matte | Polished | Brush |
| 0 | 118.1 ± 1.2 | 114.8 ± 1.6 | 116.1 ± 2.4 |
| 100 × 1 | 113.2 ± 3.5 | 111.6 ± 4.1 | 109.9 ± 2.9 |

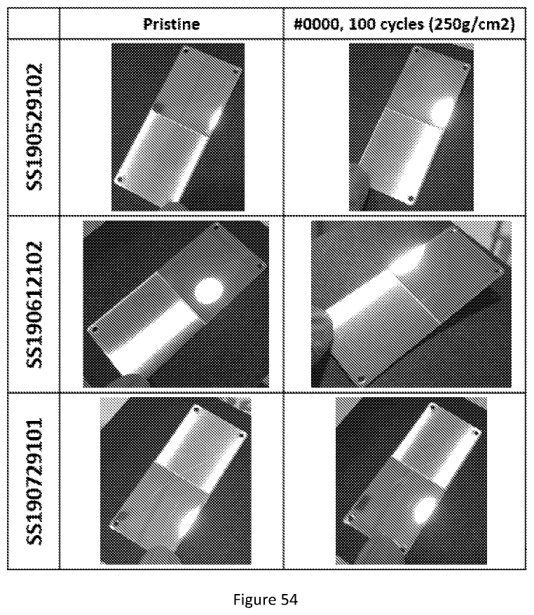

TABLE 11
Results for FIG. 54, sample SS190529102

| | |
|---|---|
| No. of | WCA (°) |

| cycles | Polished | Brush |
|---|---|---|
| 0 | 116.0 ± 2.8 | 115.0 ± 3.2 |
| 100 × 1 | 105.2 ± 2.2 | 110.4 ± 1.5 |

TABLE 12
Results for FIG. 54, sample SS190612102

| | |
|---|---|
| No. of | WCA (°) |

| cycles | Polished | Brush |
|---|---|---|
| 0 | 116.0 ± 2.4 | 114.6 ± 2.7 |
| 100 × 1 | 111.6 ± 1.0 | 112.8 ± 1.0 |

TABLE 13
Results for FIG. 54, sample SS190729101

| | |
|---|---|
| No. of | WCA (°) |

| cycles | Polished | Brush |
|---|---|---|
| 0 | 114.2 ± 2.9 | 116.0 ± 2.8 |
| 100 × 1 | 111.6 ± 1.1 | 109.3 ± 3.5 |

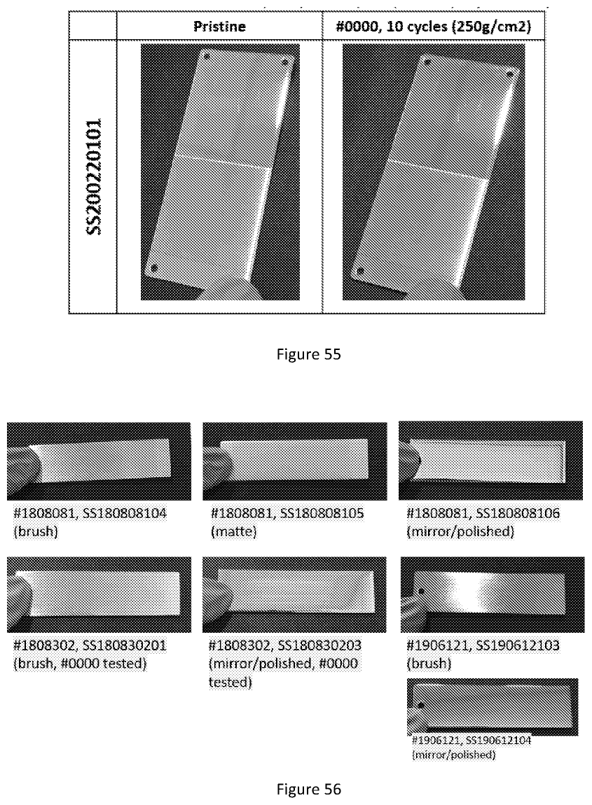

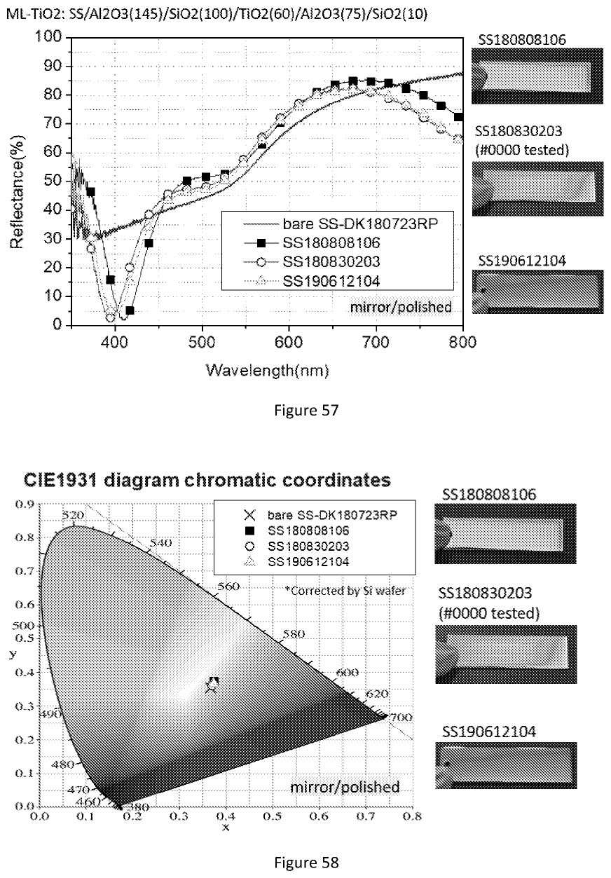

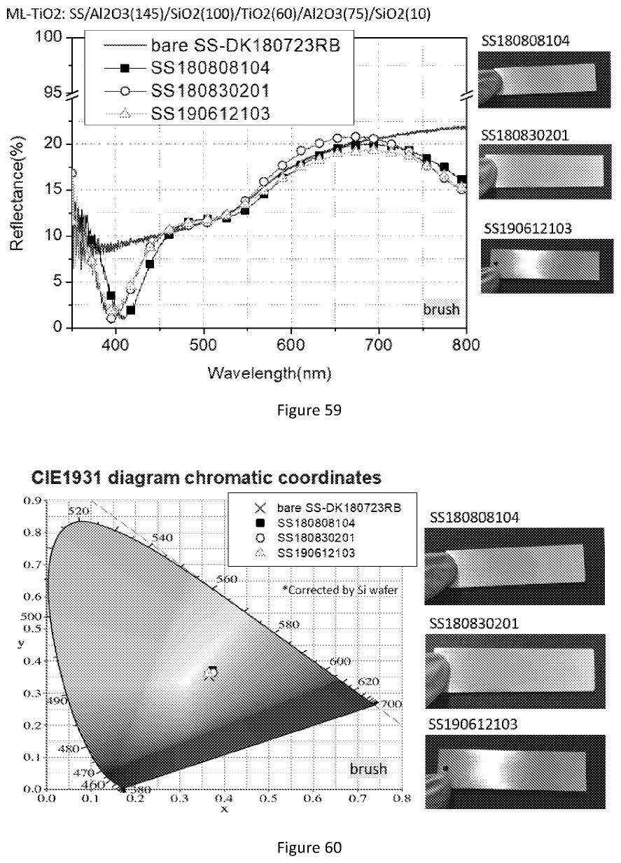

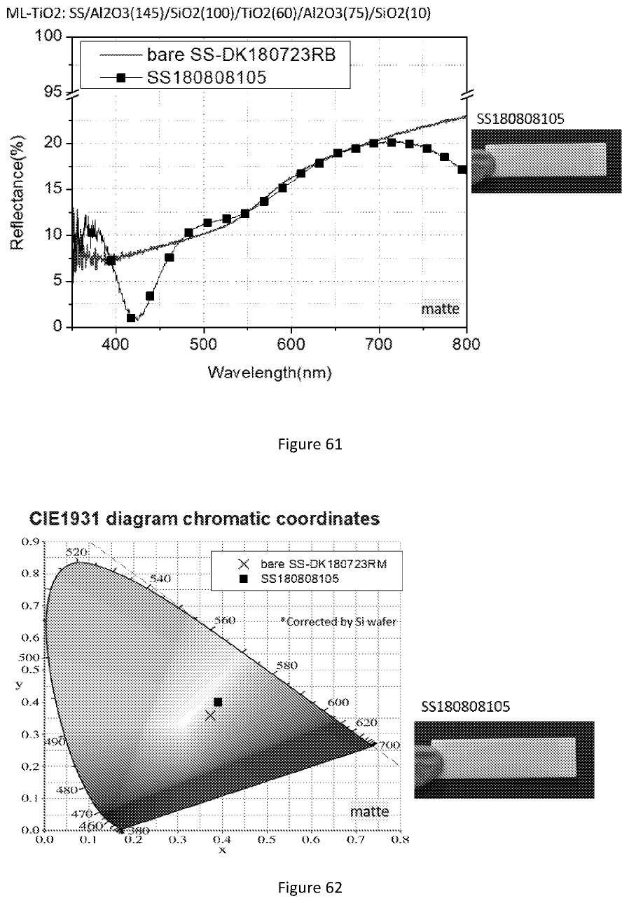

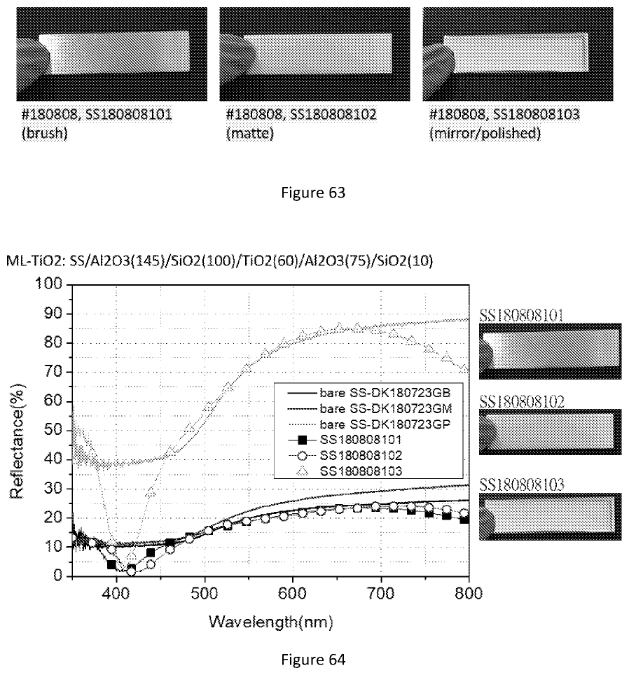

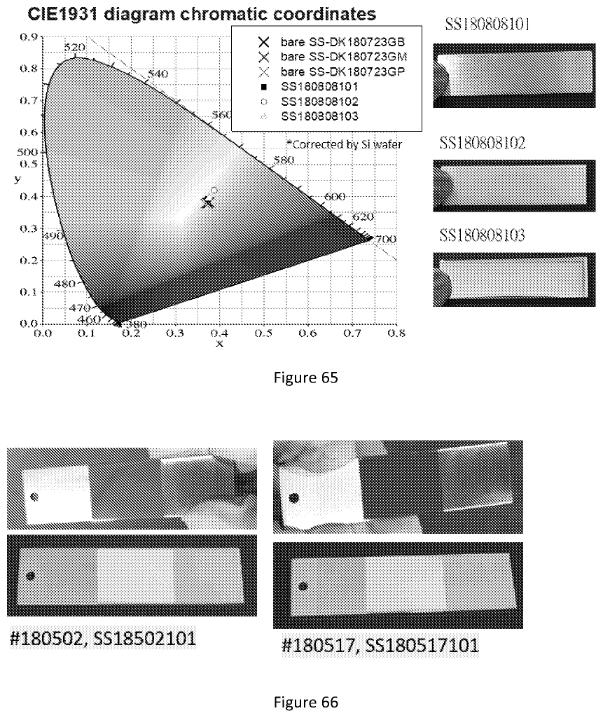

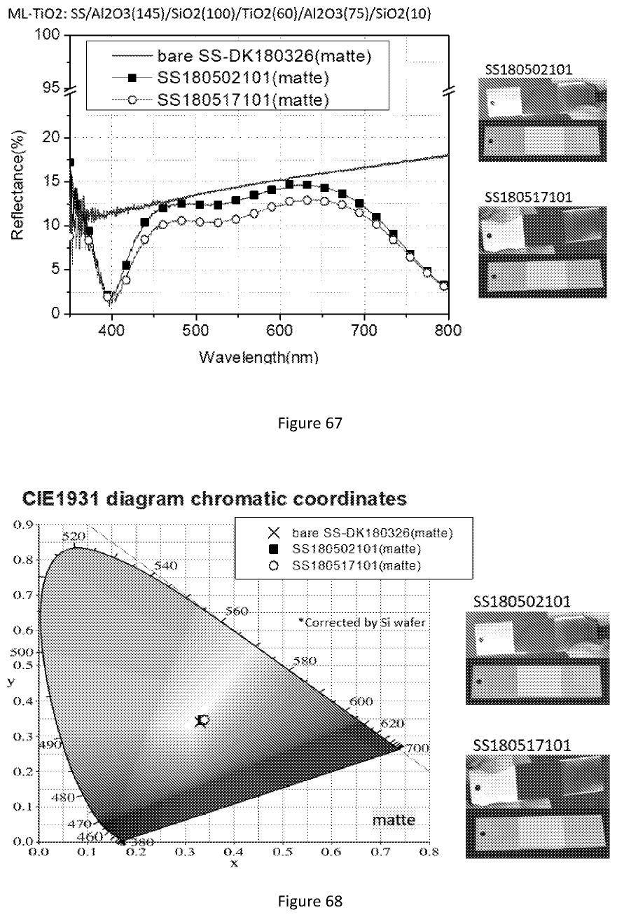

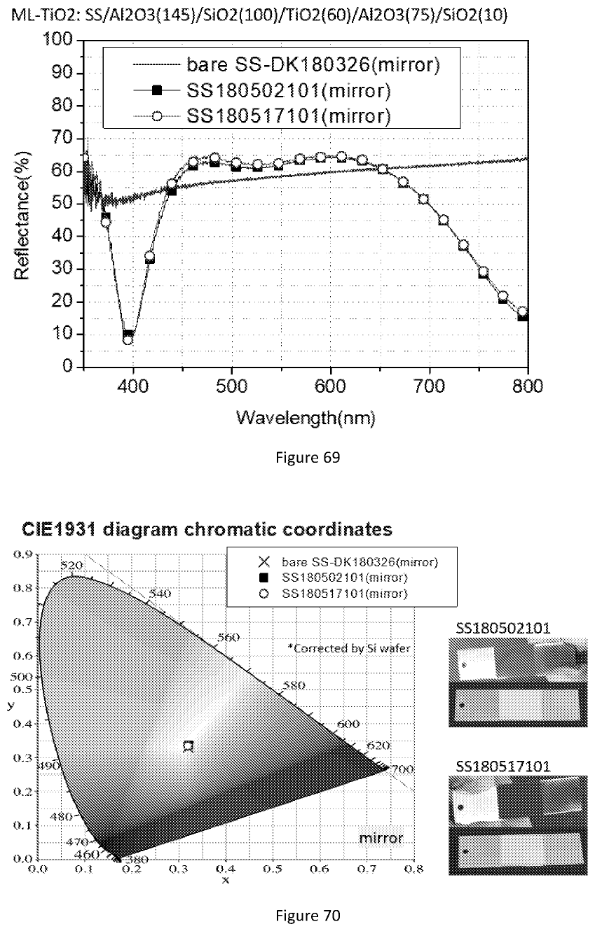

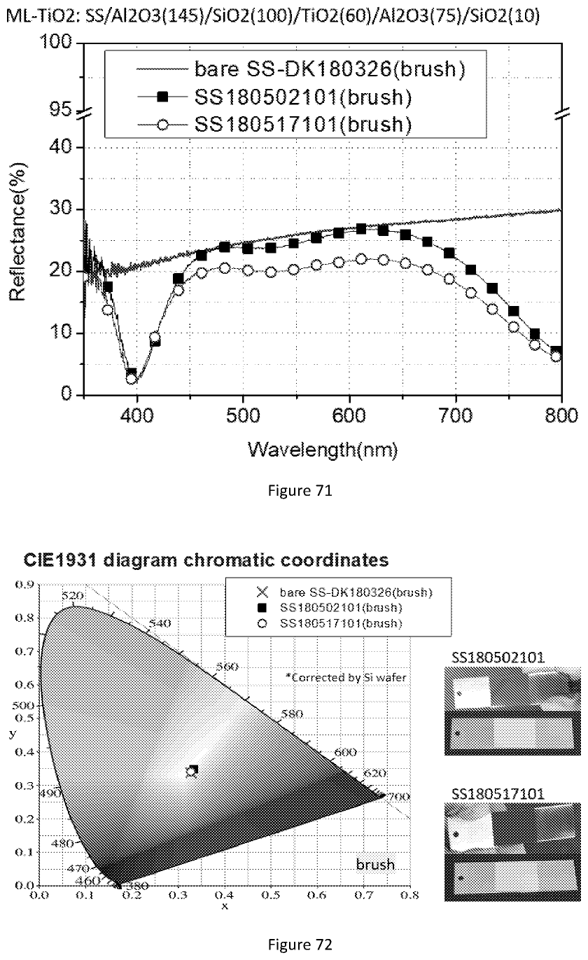

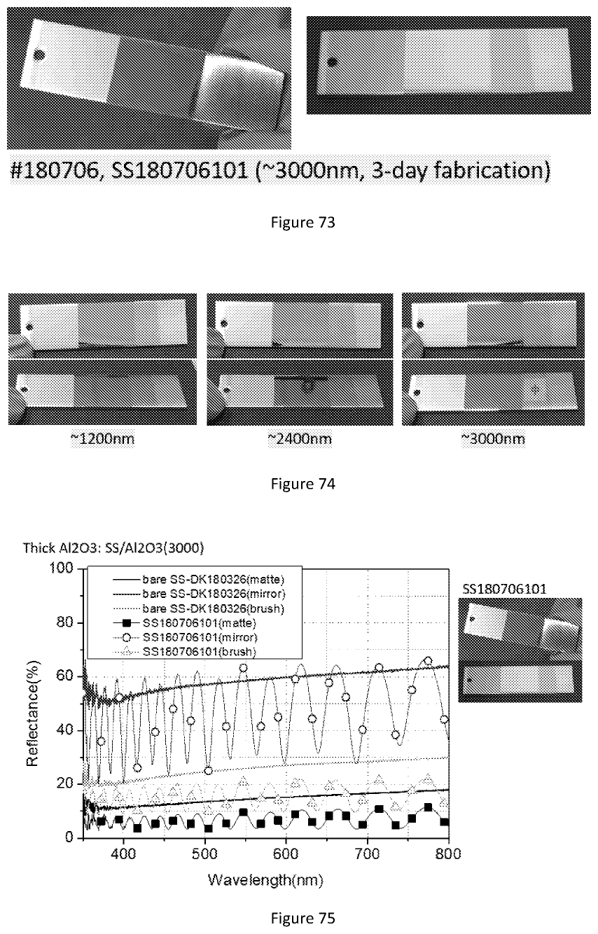

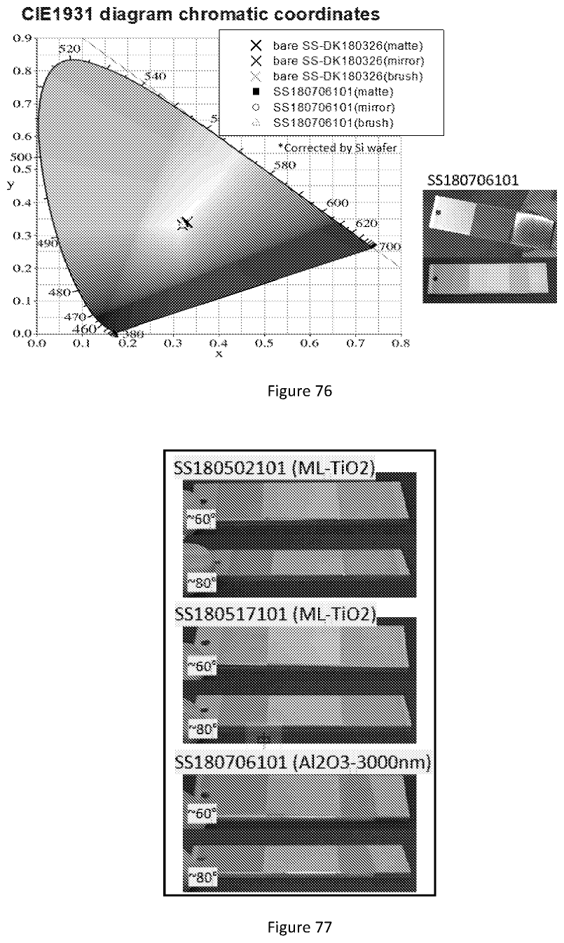

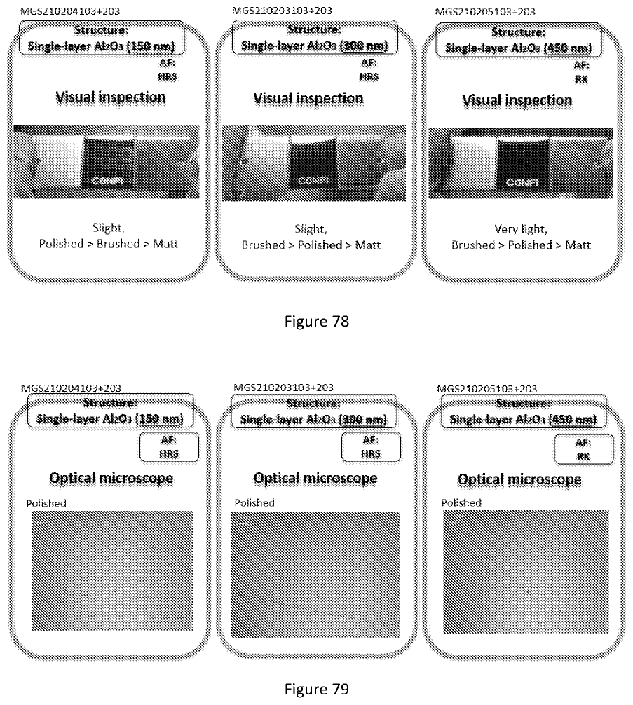

TABLE 14
Results for FIG. 55

| | |
|---|---|
| No. of | WCA (°) |

| cycles | Polished | Brush |
|---|---|---|
| 0 | 111.2 ± 1.3 | 106.8 ± 2.9 |
| 10 × 1 | 106.2 ± 1.5 | 104.2 ± 2.3 |

TABLE 15
Summary of CIExy for different samples
0° incidence, by OceanOptics

| | Ravg, | | |
|---|---|---|---|
| | 400-700 nm | CIExy | |
| Sample | (%) | x | y |
| Bare SS-DK180723Rose-gold, | 14.7 | 0.3648 | 0.3593 |
| Brush (RB) | | | |
| SS180808104 (RB) | 13.5 | 0.3732 | 0.3755 |
| SS180830201 (RB) | 14.5 | 0.3746 | 0.3681 |
| SS190612103 (RB) | 13.8 | 0.3635 | 0.3651 |
| Bare SS-DK180723Rose-gold, | 13.5 | 0.3720 | 0.3628 |
| Matte (RM) | | | |
| SS180808105 (RM) | 12.6 | 0.3896 | 0.4047 |
| Bare SS-DK180723Rose-gold, | 57.0 | 0.3665 | 0.3590 |
| Polished (RP) | | | |
| SS180808106 (RP) | 58.2 | 0.3736 | 0.3782 |
| SS180830203 (RP) | 59.3 | 0.3690 | 0.3655 |
| SS190612104 (RP) | 57.8 | 0.3729 | 0.3703 |

TABLE 16
Summary of CIExy for different samples
0° incidence, by OceanOptics

| | |
|---|---|
| Ravg, | |
| 400-700 nm | CIExy |

| Sample | (%) | x | y |
|---|---|---|---|
| Bare SS-DK180723 | 18.4 | 0.3718 | 0.3842 |
| Gold Brushed (GB) | | | |
| SS180808101 (GB) | 17.0 | 0.3734 | 0.3958 |
| Bare SS-DK180723 | 20.9 | 0.3754 | 0.3861 |
| Gold Matte (GM) | | | |
| SS180808102 (GM) | 16.5 | 0.3868 | 0.4236 |
| Bare SS-DK180723 | 65.7 | 0.3670 | 0.3822 |
| Gold Polished (GP) | | | |
| SS180808103 (GP) | 62.8 | 0.3756 | 0.3998 |

TABLE 17
Summary of CIExy for different samples
0° incidence, by OceanOptics

| | |
|---|---|
| Ravg, | |
| 400-700 nm | CIExy |

| Sample | (%) | x | y |
|---|---|---|---|
| Bare SS-DK180326(matte) | 14.3 | 0.3301 | 0.3446 |
| SS180502101(matte) | 12.3 | 0.3345 | 0.3494 |
| SS180517101(matte) | 10.6 | 0.3391 | 0.3515 |
| Bare SS-DK180326(mirror) | 58.2 | 0.3194 | 0.3353 |
| SS180502101(mirror) | 57.7 | 0.3206 | 0.3416 |
| SS180517101(mirror) | 58.6 | 0.3186 | 0.3394 |
| Bare SS-DK180326(brush) | 25.6 | 0.3266 | 0.3426 |
| SS180502101(brush) | 22.8 | 0.3330 | 0.3533 |
| SS180517101(brush) | 19.3 | 0.3262 | 0.3447 |

TABLE 18
Summary of CIExy for different samples
0° incidence, by OceanOptics

| | |
|---|---|
| Ravg, | |
| 400-700 nm | CIExy |

| Sample | (%) | x | y |
|---|---|---|---|
| Bare SS-DK180326(matte) | 14.3 | 0.3301 | 0.3446 |
| SS180706101(matte) | 6.6 | 0.3256 | 0.3384 |
| Bare SS-DK180326(mirror) | 58.2 | 0.3194 | 0.3353 |
| SS180706101(mirror) | 46.9 | 0.3198 | 0.3358 |
| Bare SS-DK180326(brush) | 25.6 | 0.3266 | 0.3426 |
| SS180706101(brush) | 15.5 | 0.3203 | 0.3368 |

TABLE 19
Summary of different samples with silver substrate

| | | Abrasion | | |
|---|---|---|---|---|
| Sample ID | Structure | cycles | AF | Visual inspection |
| Bare Silver | Bare | 100 | — | Mild, |
| (IP-210128S) | | | | Polished > |
| | | | | Brushed > Matt |
| MGS210204103 + | Al₂O₃ | 100 | HRS | Slight, |
| 203 | (150) | | | Polished > |
| | | | | Brushed > Matt |
| MGS210203103 + | Al₂O₃ | 100 | HRS | Slight, |
| 203 | (300) | | | Brushed > |
| | | | | Polished > Matt |
| MGS210205103 + | Al₂O₃ | 100 | RK | Very light, |
| 203 | (450) | | | Brushed > |
| | | | | Polished > Matt |

TABLE 20
Summary of different samples with gold substrate

| | | Abrasion | | |
|---|---|---|---|---|
| Sample ID | Structure | cycles | AF | Visual inspection |
| Bare Gold | Bare | 100 | — | Serious, |
| (IP-210128G) | | | | Brushed = |
| | | | | Polished > Matt |
| MGS210204104 + | Al₂O₃ | 100 | HRS | Very Serious, |
| 204 | (150) | | | Polished > |
| | | | | Brushed = Matt |
| MGS210203104 + | Al₂O₃ | 100 | HRS | Mild, |
| 204 | (300) | | | Polished > |
| | | | | Brushed > Matt |
| MGS210205104 + | Al₂O₃ | 100 | RK | Slight, |
| 204 | (450) | | | Polished = |
| | | | | Brushed > Matt |

TABLE 21
Summary of different samples with silver
substrate with reactive sputtering

| | | Abrasion | | Visual inspection |
|---|---|---|---|---|
| Sample ID | Structure | cycles | AF | (polished face) |
| Bare Silver | Bare | 100 | — | Mild |
| (IP-210128S) | | | | |
| MGS210317103 + 203 | Al₂O₃ | — | HRS | — |
| | (700) | | | |
| MGS210318103 + 203 | Al₂O₃ | — | HRS | — |
| | (1000) | | | |
| MGS210316103 + 203 | Al₂O₃ | 100 | HRS | Nearly no |
| | (1500) | | | |
| MGS210322103 + 203 | Al₂O₃ | — | HRS | — |
| | (2000) | | | |

TABLE 22
Summary of different samples with gold substrate with reactive sputtering

| | | Abrasion | | Visual inspection |
|---|---|---|---|---|
| Sample ID | Structure | cycles | AF | (polished face) |
| Bare Gold (IP-210128G) | Bare | 100 | — | Serious |
| MGS210317104 + 204 | Al₂O₃ (700), 2″ | 400 | HRS | Mild |
| MGS210412103 + 203 | Al₂O₃ (700), 3″ | 100 | HRS | Very light |
| MGS210318104 + 204 | Al₂O₃ (1000) | 400 | HRS | Slight |
| MGS210329103 + 203 | Al₂O₃ (1200) | 100 | HRS | Slight |
| MGS210325103 + 203 | Al₂O₃ (1300) | 100 | HRS | Slight |
| MGS210316104 + 204 | Al₂O₃ (1500), 2″ | 400 | HRS | Slight |
| MGS210323103 + 203 | Al₂O₃ (1500), 2″ | 100 | HRS | Very light |
| MGS210419103 + 203 | Al₂O₃ (1500), 3″ | 100 | HRS | Very light |
| MGS210401103 + 203 | Al₂O₃ (1700) | 100 | HRS | Slight |
| (Thickness overestimated) | | | | |
| MGS210322104 + 204 | Al₂O₃ (2000), 2″ | 400 | HRS | Slight |
| MGS210413103 + 203 | Al₂O₃ (2000), 3″ | 100 | HRS | Nearly no |

TABLE 23
Summary of different samples with Rose Gold substrate with reactive sputtering

| | | Abrasion | | Visual inspection |
|---|---|---|---|---|
| Sample ID | Structure | cycles | AF | (polished face) |
| Bare Rose Gold | Bare | 100 | — | Mild |
| (IP-210128RG) | | | | |
| MGS210317105 + 205 | Al₂O₃ (700), 2″ | 400 | HRS | Slight |
| MGS210412104 + 204 | Al₂O₃ (700), 3″ | 100 | HRS | Very light |
| MGS210318105 + 205 | Al₂O₃ (1000) | 400 | HRS | Slight |
| MGS210329104 + 204 | Al₂O₃ (1200) | 100 | HRS | Very light |
| MGS210325104 + 204 | Al₂O₃ (1300) | 100 | HRS | Nearly no |
| MGS210316105 + 205 | Al₂O₃ (1500), 2″ | 400 | HRS | Slight |
| MGS210323104 + 204 | Al₂O₃ (1500), 2″ | 100 | HRS | Very light |
| MGS210419104 + 204 | Al₂O₃ (1500), 3″ | 100 | HRS | Very light |
| MGS210401104 + 204 | Al₂O₃ (1700) | 100 | HRS | Very light |
| (Thickness overestimated) | | | | |
| MGS210322105 + 205 | Al₂O₃ (2000), 2″ | 400 | HRS | Very light |
| MGS210413104 + 204 | Al₂O₃ (2000), 3″ | 100 | HRS | Nearly no |

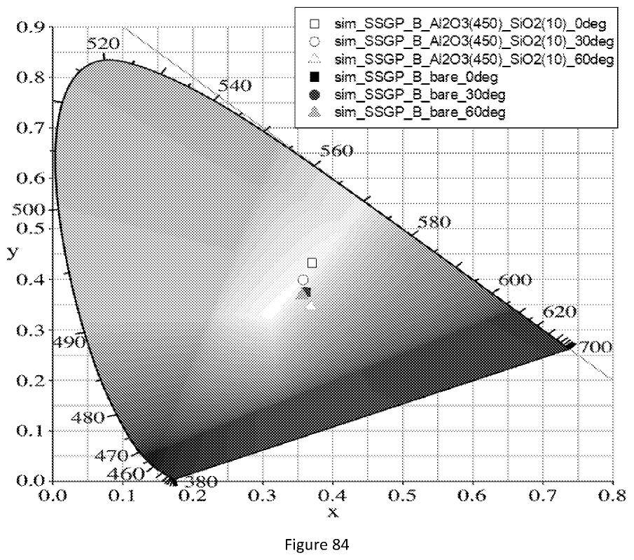

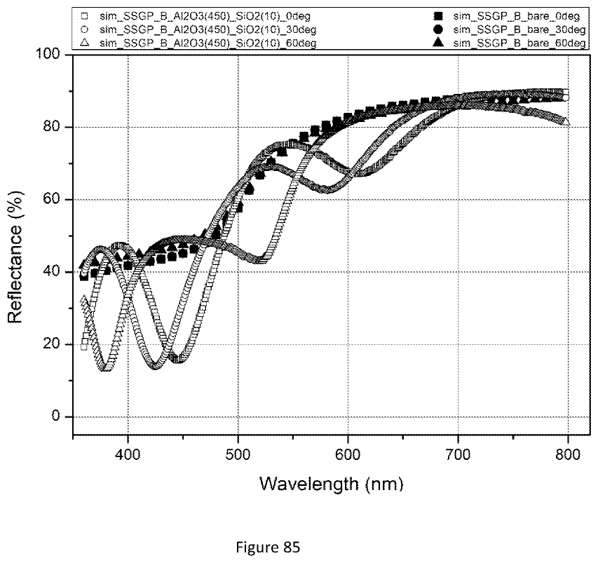

TABLE 24
Coating conditions for FIG. 84, FIG. 85

| Structure | sub/Al₂O₃ (450)/SiO₂ (10)/AF | | | | | |
|---|---|---|---|---|---|---|
| Coating | Power | Al₂O₃ | RF 120 W | Gas | Al₂O₃ | Ar 20 sccm |
| Conditions | | TiO₂ | — | | TiO₂ | — |
| | | SiO₂ | RF 150 W | | SiO₂ | Ar 20 sccm |

TABLE 25
Results for FIG. 84

| | Bare | | Sub/SiO₂ (50)/6 L | | | | |
|---|---|---|---|---|---|---|---|
| IA (deg) | x | y | x | y | Δx | Δy | Δxy |
| 0 | 0.3611 | 0.3786 | 0.3708 | 0.4366 | 0.0097 | 0.058 | 0.0588 |
| 30 | 0.3609 | 0.3783 | 0.3579 | 0.4031 | −0.003 | 0.0248 | 0.0250 |
| 60 | 0.3559 | 0.3733 | 0.3687 | 0.3495 | 0.0128 | −0.0238 | 0.0270 |

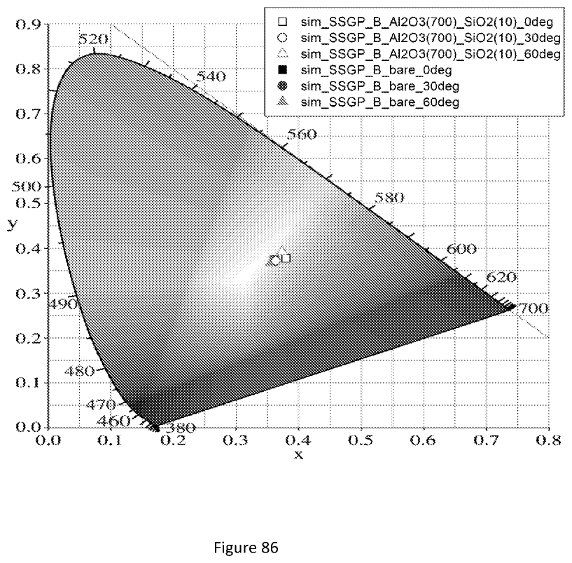

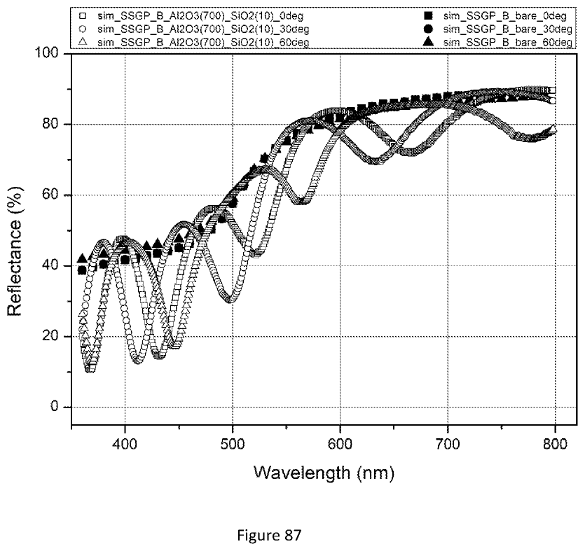

TABLE 26
Coating conditions for FIG. 86, FIG. 87

| Structure | sub/Al₂O₃ (700)/SiO₂ (10)/AF | | | | | |
|---|---|---|---|---|---|---|
| Coating | Power | Al₂O₃ | RF 120 W | Gas | Al₂O₃ | Ar 20 sccm |
| Conditions | | TiO₂ | — | | TiO₂ | — |
| | | SiO₂ | RF 150 W | | SiO₂ | Ar 20 sccm |

TABLE 27
Results for FIG. 86

| IA | Bare | | Sub/SiO₂ (50)/6 L | | | | |
|---|---|---|---|---|---|---|---|
| (deg) | x | y | x | y | Δx | Δy | Δxy |
| 0 | 0.3611 | 0.3786 | 0.3799 | 0.3821 | 0.0188 | 0.0035 | 0.0191 |
| 30 | 0.3609 | 0.3783 | 0.3636 | 0.3768 | 0.0027 | −0.0015 | 0.0031 |
| 60 | 0.3559 | 0.3733 | 0.3733 | 0.3971 | 0.0174 | 0.0238 | 0.0295 |

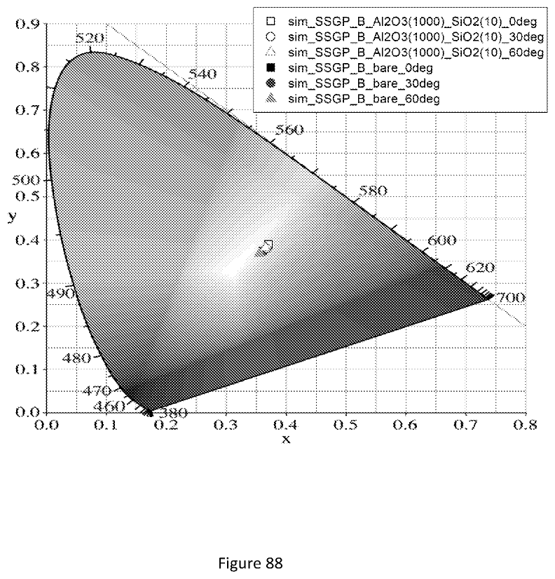

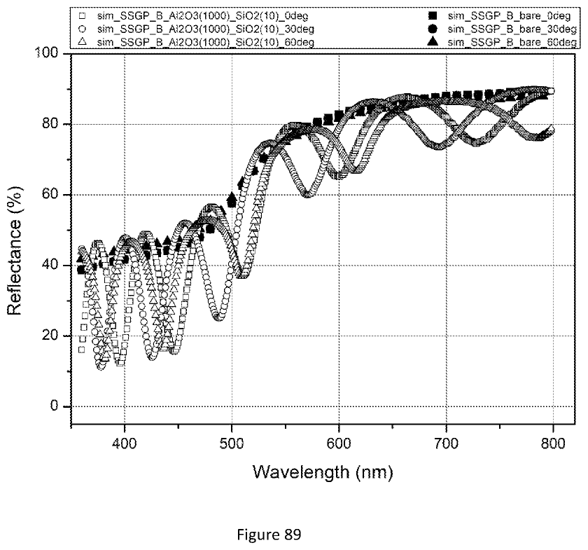

TABLE 28
Coating conditions for FIG. 88, FIG. 89

| Structure | sub/Al₂O₃ (1 μm)/SiO₂ (10)/AF | | | | | |
|---|---|---|---|---|---|---|
| Coating | Power | Al₂O₃ | RF 120 W | Gas | Al₂O₃ | Ar 20 sccm |
| Conditions | | TiO₂ | — | | TiO₂ | — |
| | | SiO₂ | RF 150 W | | SiO₂ | Ar 20 sccm |

TABLE 29
Results for FIG. 88

| IA | Bare | | Sub/SiO₂ (50)/6 L | | | | |
|---|---|---|---|---|---|---|---|
| (deg) | x | y | x | y | Δx | Δy | Δxy |
| 0 | 0.3611 | 0.3786 | 0.3708 | 0.3938 | 0.0097 | 0.0152 | 0.0180 |
| 30 | 0.3609 | 0.3783 | 0.3685 | 0.3847 | 0.0076 | 0.0064 | 0.0099 |
| 60 | 0.3559 | 0.3733 | 0.3653 | 0.3862 | 0.0094 | 0.0129 | 0.0160 |

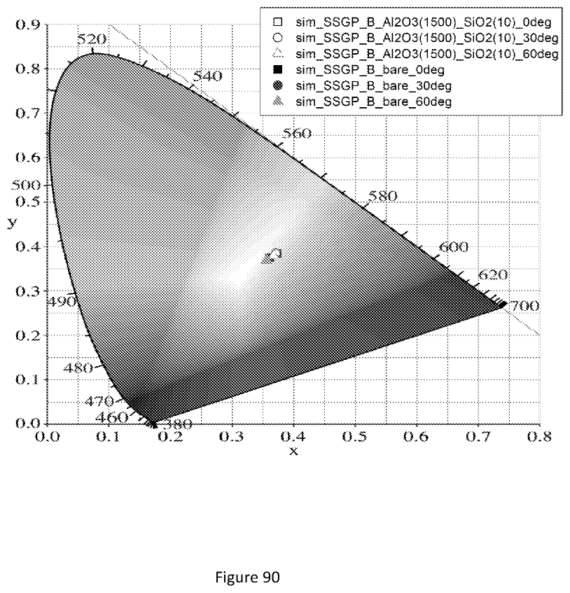

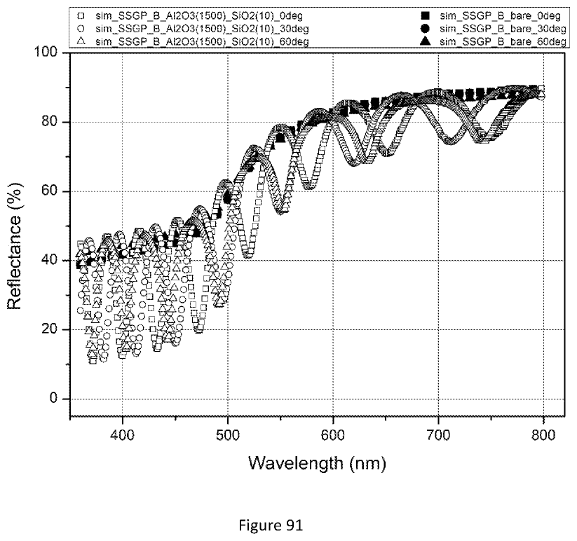

TABLE 30
Coating conditions for FIG. 90, FIG. 91

| Structure | sub/Al₂O₃ (1.5 μm)/SiO₂ (10)/AF | | | | | |
|---|---|---|---|---|---|---|
| Coating | Power | Al₂O₃ | RF 120 W | Gas | Al₂O₃ | Ar 20 sccm |
| Conditions | | TiO₂ | — | | TiO₂ | — |
| | | SiO₂ | RF 150 W | | SiO₂ | Ar 20 sccm |

TABLE 31
Results for FIG. 90

| IA | Bare | | Sub/SiO₂ (50)/6 L | | | | |
|---|---|---|---|---|---|---|---|
| (deg) | x | y | x | y | Δx | Δy | Δxy |
| 0 | 0.3611 | 0.3786 | 0.3732 | 0.3883 | 0.0121 | 0.0097 | 0.0155 |
| 30 | 0.3609 | 0.3783 | 0.3709 | 0.3889 | 0.01 | 0.0106 | 0.0146 |
| 60 | 0.3559 | 0.3733 | 0.3676 | 0.384 | 0.0117 | 0.0107 | 0.0159 |

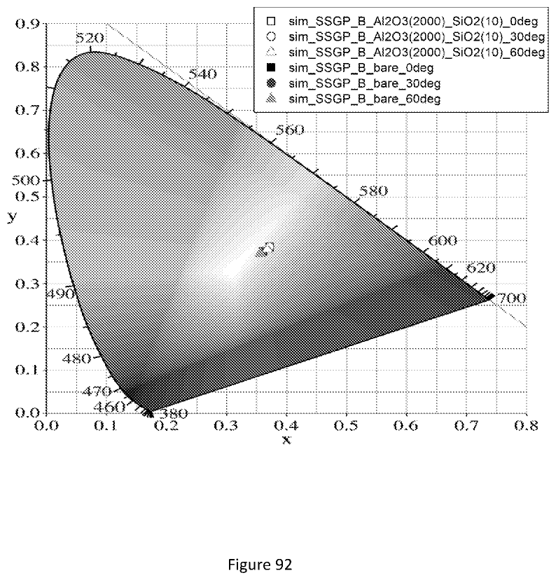

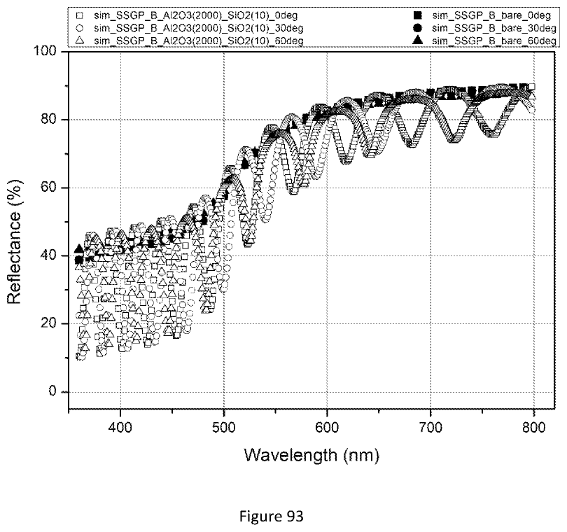

TABLE 32
Coating conditions for FIG. 92, FIG. 93

| Structure | sub/Al₂O₃ (2 μm)/SiO₂ (10)/AF | | | | | |
|---|---|---|---|---|---|---|
| Coating | Power | Al₂O₃ | RF 120 W | Gas | Al₂O₃ | Ar 20 sccm |
| Conditions | | TiO₂ | — | | TiO₂ | — |
| | | SiO₂ | RF 150 W | | SiO₂ | Ar 20 sccm |

TABLE 33
Results for FIG. 92

| IA | Bare | | Sub/SiO₂ (50)/6 L | | | | |
|---|---|---|---|---|---|---|---|
| (deg) | x | y | x | y | Δx | Δy | Δxy |
| 0 | 0.3611 | 0.3786 | 0.3719 | 0.3885 | 0.0108 | 0.0099 | 0.0147 |
| 30 | 0.3609 | 0.3783 | 0.3721 | 0.3891 | 0.0112 | 0.0108 | 0.0156 |
| 60 | 0.3559 | 0.3733 | 0.368 | 0.3834 | 0.0121 | 0.0101 | 0.0158 |

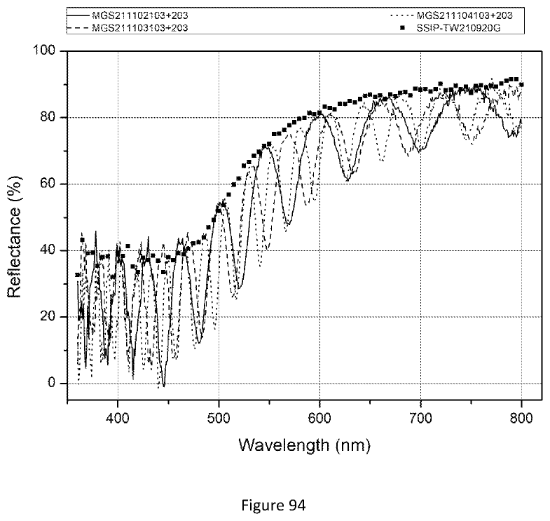

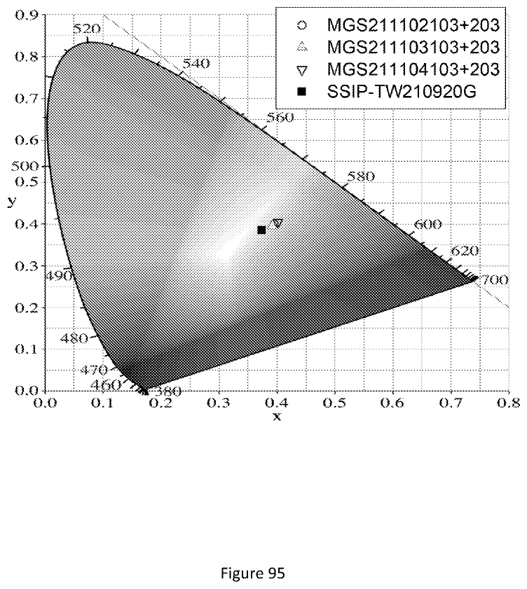

TABLE 34
Coating conditions for FIG. 94, FIG. 95

| Structure | Sub/Al₂O₃ (1500-3000)/SiO₂ (10)/AF-HRS(30) | | | | | |
|---|---|---|---|---|---|---|
| Coating | Power | Al | DC 130 W | Gas | Al | Ar 20 sccm |
| Conditions | | | | | | O2 3.0-3.7 sccm |
| | | SiO₂ | RF 100 W | | SiO₂ | Ar 20 sccm |

TABLE 35
Results for FIG. 95

| | IA = 0 deg | | | | Δx | Δy | Δx | Δy |
|---|---|---|---|---|---|---|---|---|
| Structure | x | y | x | y | (with | (with | (with | (with |
| (nm) | (sim) | (sim) | (mea) | (mea) | sim) | sim) | bare) | bare) |
| bare | 0.3681 | 0.3856 | 0.3737 | 0.3891 | 0.0056 | 0.0035 | — | — |
| Al₂O₃ | 0.3807 | 0.3986 | 0.3950 | 0.4037 | 0.0143 | 0.0051 | 0.0213 ± | 0.0146 ± |
| (1500, DC) | | | | | | | 0.001 | 0.001 |
| Al₂O₃ | 0.3822 | 0.3992 | 0.3918 | 0.3993 | 0.0096 | 1E−04 | 0.0181 ± | 0.0102 ± |
| (2000, DC) | | | | | | | 0.001 | 0.001 |
| Al₂O₃ | 0.3825 | 0.3998 | 0.4013 | 0.4084 | 0.0188 | 0.0086 | 0.0276 ± | 0.0193 ± |
| (3000, DC) | | | | | | | 0.001 | 0.001 |

TABLE 36
Results for FIG. 95

| | IA = 0 deg | | | | | ΔL | ΔE |
|---|---|---|---|---|---|---|---|
| Structure | x | y | x | y | | (with | (with |
| (nm) | (sim) | (sim) | (mea) | (mea) | L | bare) | bare) |
| bare | 0.3681 | 0.3856 | 0.3737 | 0.3891 | 87.7 | — | — |
| Al₂O₃ (1500, DC) | 0.3807 | 0.3986 | 0.3950 | 0.4037 | 81.1 | −6.6 ± 0.3 | 9.9 ± 0.3 |
| Al₂O₃ (2000, DC) | 0.3822 | 0.3992 | 0.3918 | 0.3993 | 80.9 | 6.8 ± 0.3 | 8.8 ± 0.3 |
| Al₂O₃ (3000,DC) | 0.3825 | 0.3998 | 0.4013 | 0.4084 | 80.3 | −7.4 ± 0.3 | 12.4 ± 0.3 |

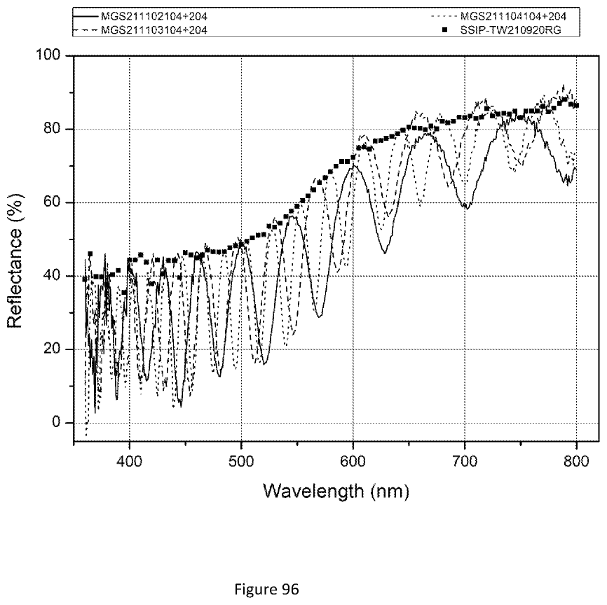

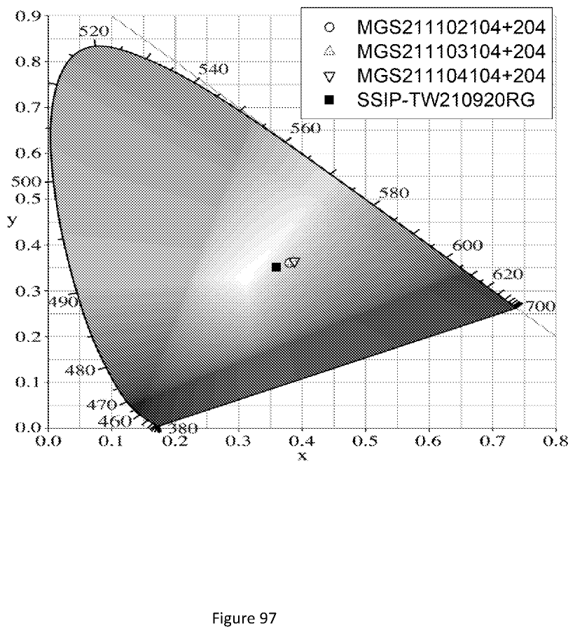

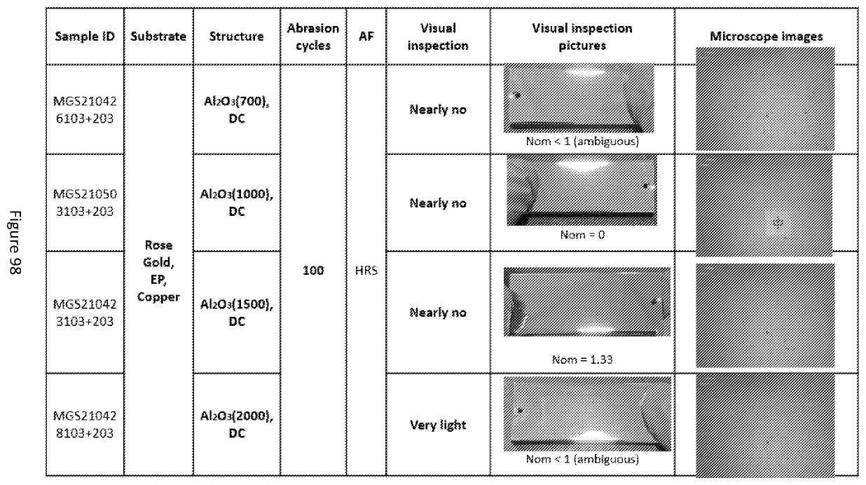

TABLE 37
Coating conditions for FIG. 96, FIG. 97

| Structure | Sub/Al₂O₃ (1500-3000)/SiO₂ (10)/AF-HRS(30) | | | | | |
|---|---|---|---|---|---|---|
| Coating | Power | Al | DC 130 W | Gas | Al | Ar 20 sccm |
| Conditions | | | | | | O2 3.0-3.7 sccm |
| | | SiO₂ | RF 100 W | | SiO₂ | Ar 20 sccm |

TABLE 38
Results for FIG. 97

| | IA = 0 deg | | | | Δx | Δy | Δx | Δy |
|---|---|---|---|---|---|---|---|---|
| Structure | x | y | x | y | (with | (with | (with | (with |
| (nm) | (sim) | (sim) | (mea) | (mea) | sim) | sim) | bare) | bare) |
| bare | 0.3543 | 0.3546 | 0.3593 | 0.3554 | 0.005 | 0.0008 | — | — |
| Al₂O₃ | 0.3662 | 0.3621 | 0.3799 | 0.3648 | 0.0137 | 0.0027 | 0.0206 ± | 0.0094 ± |
| (1500, DC) | | | | | | | 0.001 | 0.001 |
| Al₂O₃ | 0.3680 | 0.3629 | 0.3853 | 0.3676 | 0.0173 | 0.0047 | 0.0260 ± | 0.0122 ± |
| (2000, DC) | | | | | | | 0.001 | 0.001 |
| Al₂O₃ | 0.3682 | 0.3633 | 0.3877 | 0.3689 | 0.0195 | 0.0056 | 0.0284 ± | 0.0135 ± |
| (3000, DC) | | | | | | | 0.001 | 0.001 |

TABLE 39
Results for FIG. 97

| | | | | | | ΔL | ΔE |
|---|---|---|---|---|---|---|---|
| Structure | x | y | x | y | | (with | (with |
| (nm) | (sim) | (sim) | (mea) | (mea) | L | bare) | bare) |
| bare | 0.3543 | 0.3546 | 0.3593 | 0.3554 | 82.6 | — | — |
| Al₂O₃ (1500, DC) | 0.3662 | 0.3621 | 0.3799 | 0.3648 | 73.1 | −9.6 ± 0.4 | 11.1 ± 0.4 |
| Al₂O₃ (2000, DC) | 0.3680 | 0.3629 | 0.3853 | 0.3676 | 76.0 | −6.7 ± 0.4 | 10.7 ± 0.4 |
| Al₂O₃ (3000, DC) | 0.3682 | 0.3633 | 0.3877 | 0.3689 | 74.6 | −8.0 ± 0.4 | 11.9 ± 0.4 |

TABLE 49
Summary for 100 abrasion cycles (DC, 3-inch Al
target) for Substrates: EP-CF210421RG (Copper)

| | | Abrasion | | Visual |
|---|---|---|---|---|
| Sample ID | Structure | cycles | AF | inspection |
| CuEP-CF210421RG | Bare | 100 | — | Slight |
| MGS210426103 + 203 | Al₂O₃ (700) | 100 | HRS | Nearly no |
| MGS210503103 + 203 | Al₂O₃ (1000) | 100 | HRS | Nearly no |
| MGS210423103 + 203 | Al₂O₃ (1500) | 100 | HRS | Nearly no |
| MGS210428103 + 203 | Al₂O₃ (2000) | 100 | HRS | Very light |

TABLE 50
Summary for 400 abrasion cycles (DC, 3-inch Al
target) for Substrates: EP-CF210421RG (Copper)

| | | Abrasion | | Visual |
|---|---|---|---|---|
| Sample ID | Structure | cycles | AF | inspection |
| CuEP-CF210421RG | Bare | 400 | — | Mild |
| MGS210426103 + 203 | Al₂O₃ (700) | 400 | HRS | Very light |
| MGS210503103 + 203 | Al₂O₃ (1000) | 400 | HRS | Slight |
| MGS210423103 + 203 | Al₂O₃ (1500) | 400 | HRS | Very light |
| MGS210428103 + 203 | Al₂O₃ (2000) | 400 | HRS | Slight |

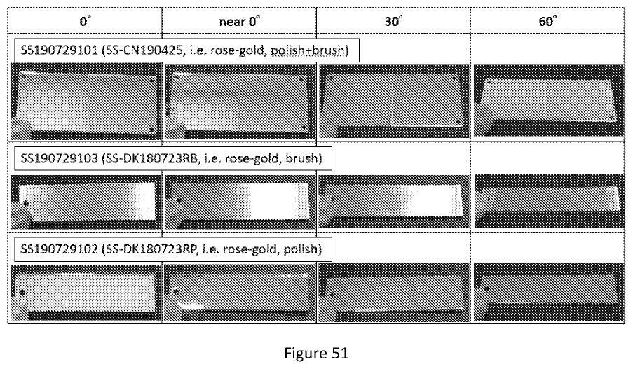

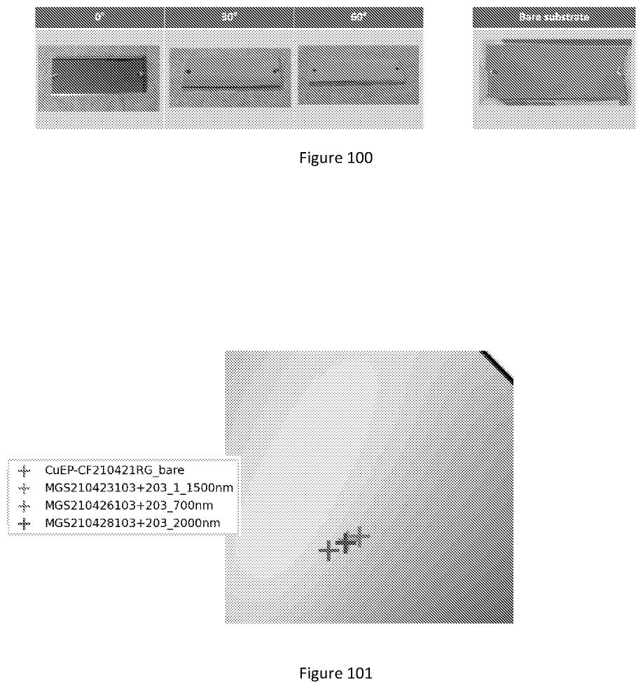

FIG. 51 Coating conditions for FIG. 100, FIG. 101

| Structure | sub/Al₂O₃ (x)/SiO₂ (10), x = 700 nm, 1, 1.5, 2 μm | | | | | |
|---|---|---|---|---|---|---|
| Coating | Power | Al | DC 130 W | Gas | Al | Ar 20 sccm |
| Conditions | | | | | | O2 3.5-3.7 sccm |
| | | TiO₂ | — | | TiO₂ | — |
| | | SiO₂ | RF 100 W | | SiO₂ | Ar 20 sccm |

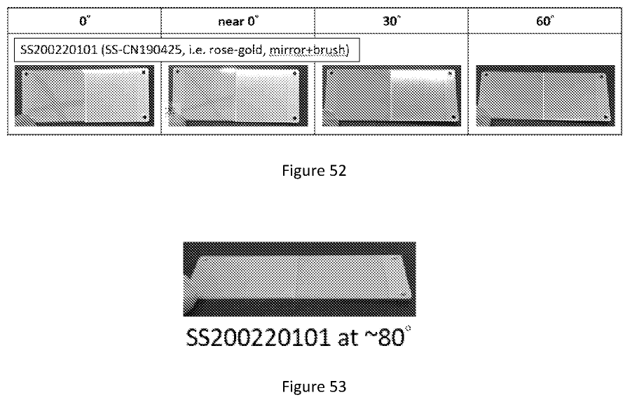

FIG. 52 Results for FIG. 101

| | IA = 0 deg | | | | Δx | Δy |
|---|---|---|---|---|---|---|
| Thickness | x | y | x | y | (with | (with |
| (x, μm) | (sim) | (sim) | (mea) | (mea) | sim) | sim) |
| bare | 0.3553 | 0.3531 | 0.3558 | 0.3529 | 0.0005 | −0.0002 |
| 0.7 | 0.3819 | 0.36 | 0.3813 | 0.3650 | −0.0006 | 0.005 |
| 1 | 0.3718 | 0.3575 | (pending) | | | |
| 1.5 | 0.3675 | 0.3591 | 0.3714 | 0.3615 | 0.0039 | 0.0024 |
| 2 | 0.3689 | 0.36 | 0.3696 | 0.3593 | 0.0007 | −0.0007 |

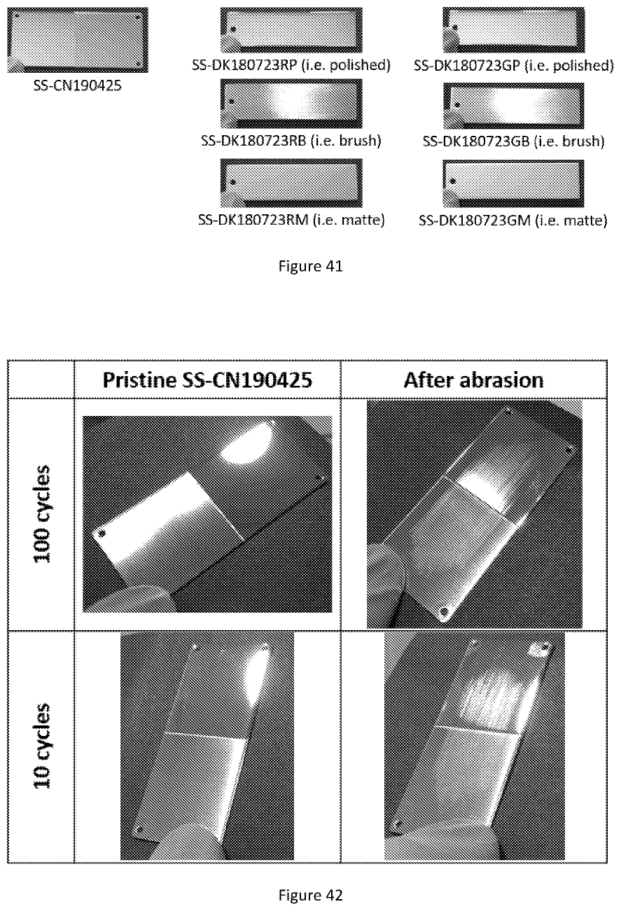

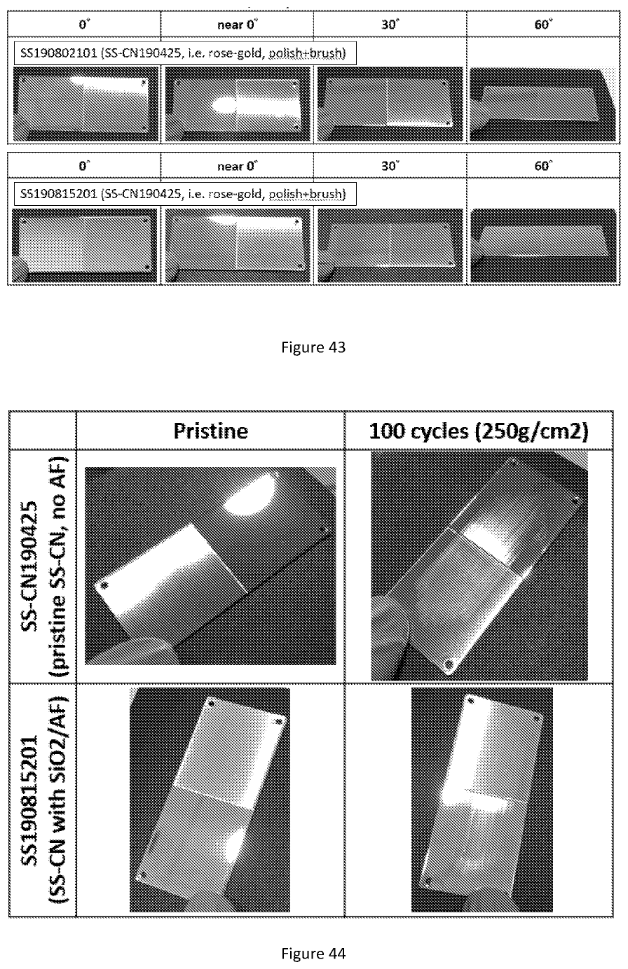

Embodiments of the present invention are represented by metal substrates as listed in Table 5-52 and in examples presented in FIGS. 41 to 101.

### INDUSTRIAL APPLICABILITY

This invention related to a composite thin film including a coated film with sapphire (Al₂O₃) and SiO₂, ZrO₂/TiO₂ on metal substrate, which has a high abrasion resistance, an excellent adhesiveness and consistent appearance color with bare metal substrate. The present invention has applications in providing for an EB and/or sputtering-based transparent or translucent thin film coating on metal substrates that have characteristics such as an attractive appearance, abrasion resistance, color consistency with the metal substrate, and/or insulation.

As used herein, terms “approximately”, “basically”, “substantially”, and “about” are used for describing and explaining a small variation. When being used in combination with an event or circumstance, the term may refer to a case in which the event or circumstance occurs precisely, and a case in which the event or circumstance occurs approximately. As used herein with respect to a given value or range, the term “about” generally means in the range of ±10%, ±5%, ±1%, or ±0.5% of the given value or range. The range may be indicated herein as from one endpoint to another endpoint or between two endpoints. Unless otherwise specified, all the ranges disclosed in the present disclosure include endpoints. The term “substantially coplanar” may refer to two surfaces within a few micrometers (μm) positioned along the same plane, for example, within 10 μm, within 5 μm, within 1 μm, or within 0.5 μm located along the same plane. When reference is made to “substantially” the same numerical value or characteristic, the term may refer to a value within ±10%, ±5%, ±1%, or ±0.5% of the average of the values.

Several embodiments of the present disclosure and features of details are briefly described above. The embodiments described in the present disclosure may be easily used as a basis for designing or modifying other processes and structures for realizing the same or similar objectives and/or obtaining the same or similar advantages introduced in the embodiments of the present disclosure. Such equivalent construction does not depart from the spirit and scope of the present disclosure, and various variations, replacements, and modifications can be made without departing from the spirit and scope of the present disclosure.

1. A composite multi-layer thin film structure deposited on a metal substrate by electron beam evaporation or sputtering, the multi-layer thin film structure comprising:
a metal substrate;
a first thin film layer of on a surface of the metal substrate comprising Al₂O₃ with a thickness ranging from approximately 100 nm to 150 nm and a refractive index of approximately 1.7;
a second thin film layer positioned on the first thin film layer, the second thin film layer comprising SiO₂ with a thickness ranging from approximately 80 nm to 120 nm and a refractive index of approximately 1.4;
a third thin film layer positioned on the second thin film layer comprising TiO₂ with a thickness ranging from approximately 50 nm to 80 nm and a refractive index of approximately 2.2;
a fourth thin film layer positioned on the third film layer comprising Al₂O₃ with a thickness ranging from approximately 60 nm to 90 nm; wherein the total thickness of the multi-layer thin film structure deposited on the metal substrate ranges from approximately 280 nm to 400 nm.

2. The multi-layer thin film structure according to claim 1, further comprising a fifth thin film layer positioned on the fourth thin film layer comprising SiO₂ with a thickness ranging from approximately 10 nm to 20 nm.

3. The multi-layer thin film structure according to claim 1, wherein the thin film layers are deposited at a temperature of approximately 25 degrees Celsius.

4. The multi-layer thin film structure according to claim 1, further comprising an anti-fingerprint (AF) coating on the fifth thin film layer.

5. The multi-layered structure of thin films according to claim 1 wherein the metal substrate comprises stainless steel.

6. A method for depositing a composite multi-layered thin film structure on a metal substrate by electron beam evaporation or sputtering, the method comprising:
providing a metal substrate;
depositing a first thin film layer on a surface of the metal substrate comprising Al₂O₃ with a thickness ranging from approximately 100 nm to 150 nm and a refractive index of approximately 1.7;
depositing a second thin film layer on the first thin film layer, the second thin film layer comprising SiO₂ with a thickness ranging from approximately 80 nm to 120 nm and a refractive index of approximately 1.4;
depositing a third thin film layer on the second thin film layer, the third film layer comprising TiO₂ with a thickness ranging from approximately 50 nm to 80 nm and a refractive index of approximately 2.2; and
depositing a fourth thin film layer on the third thin film layer, the fourth thin film layer comprising Al₂O₃ with a thickness ranging from approximately 60 nm to 90 nm, wherein a total thickness of the multi-layered thin film structure deposited on the metal substrate ranges from approximately 280 nm to 400 nm.

7. The method according to claim 6, further comprising depositing a fifth thin film layer on the fourth thin film layer, the fifth thin film layer comprising SiO₂ with a thickness ranging from approximately 10 nm to 20 nm.

8. The method according to claim 7, further comprising depositing an anti-fingerprint coating on the fifth thin film layer.

9. The method according to claim 6 wherein the thin film layers are deposited at a temperature of approximately 15-25 degrees Celsius.

10. The method according to claim 6 wherein the thin film layers are deposited without heating or cooling of the metal substrate, without heating or cooling of the thin film material targets, and without heating or cooling of the deposition environment.

11. The method according to claim 6 wherein the thin film layers are deposited without preheating or post-heating, or pre-cooling or post cooling of the metal substrate, the thin film material targets or the deposition environment.

12. The method according to claim 6 wherein the thin film layers are deposited with no post annealing of the deposited thin film on the metal substrate.

13. The method according to claim 6 wherein the thin film layers are deposited sequentially while maintaining a vacuum condition of an electron beam or sputtering deposition system.

14. The method according to claim 6 wherein the metal substrate comprises stainless steel.

15. An anti-abrasion protective thin film structure deposited on a metal substrate by electron sputtering comprising:
a metal substrate;
at least a first layer positioned on a surface of the metal substrate, the first layer comprising Al₂O₃ with a thickness up to 2000 nm and a refractive index of about 1.7.

16. The anti-abrasion protective thin film structure of claim 15, further comprising second layer comprising SiO₂ layer positioned on a surface of the first layer comprising Al₂O₃.

17. The anti-abrasion protective thin film structure of claim 15, further comprising an anti-fingerprint coating positioned on a surface of the first layer comprising Al₂O₃.

18. The anti-abrasion protective thin film structure of claim 16, further comprising an anti-fingerprint coating positioned on a surface of the second layer comprising SiO₂.
